(19) United States
(12) Patent Application Publication
(10) Pub. No.: US 2005/0184348 A1
(43) Pub. Date: Aug. 25, 2005

(54) Semiconductor device gate structure and method of forming the same

(76) Inventors: Jae-Man Youn, Seoul (KR); Dong-Gun Park, Gyeonggi-do (KR); Choong-Ho Lee, Gyeonggi-do (KR); Makoto Yoshida, Gyeonggi-do (KR); Chul Lee, Seoul (KR)

Correspondence Address: MARGER JOHNSON & MCCOLLOM, P.C., 1030 SW MORRISON STREET, PORTLAND, OR, 97205, US

(21) Appl. No.: 11/059,145

(22) Filed: Feb. 15, 2005

(30) Foreign Application Priority Data
Feb. 19, 2004 (KR) 2004-10882

(51) Int. Cl. H01L 27/12

(52) U.S. Cl. 257/401

(57) ABSTRACT

A MOS transistor includes a gate structure extending forrom a semiconductor substrate in a vertical direction is disclosed. The gate structure includes a gate electrode extending from the substrate in a vertical direction, and a gate insulation layer enclosing the gate electrode. A channel pattern encloses the gate insulation layer, and a first conductive pattern extends from a lower portion of the channel pattern in a first direction verticalperpendicular to the channel pattern and in parallel with the substrate. A second conductive pattern extends from an upper portion of the channel pattern in a second direction verticalperpendicular to the channel pattern and in parallel with the substrate. Accordingly, the channel length of the MOS transistor is determined by a distance between the first and second conductive patterns, and a channel width of the MOS transistor is determined by a diameter of the gate structure. Short channel and narrow width effects are sufficiently prevented in a MOS transistor.

### CROSS-REFERENCE TO RELATED APPLICATIONS

This application relies for priority upon Korean Patent Application No. 2004-10882 filed on Feb. 19, 2004, the content of which is herein incorporated by reference in its entirety.

### BACKGROUND OF THE INVENTION

1. Field of the Invention

This disclosure relates to a semiconductor device and a method of manufacturing the same. More particularly, disclosure relates to a gate structure and a metal oxide semiconductor (MOS) transistor having the gate structure and a method of forming the gate structure and the MOS transistor.

2. Description of the Related Art

As semiconductor devices become more highly integrated, active regions, in where various conductive structures are positioned become reduced in a size and a channel length ofin the a MOS transistor in the active region is also shortened. When the channel length is decreased, a source or a drain of the MOS transistor has much more an increased effect on an electrical field or a voltage in a channel region. This is, which is called as a short channel effect. In addition, when the size of the active region is reduced, a width of the channel of the MOS transistor is also reduced, thereby increasing a threshold voltage of the MOS transistor, which is called as a narrow channel effect, or a narrow width effect.

Accordingly, recent researches and developments haves been focused onfor reducing the size of a conductive structure in a semiconductor device without decreasing a performance of the semiconductor devices. A vertical transistor such as a fin structure, a fully depleted lean-channel structure, and a gate all around structure is are common examples.

U.S. Pat. No. 6,413,082 exemplarily discloses a fin-structured MOS transistor, in which a plurality of thin channel fins is positioned between the source/drain regions, and a gate electrode extends to a top surface and sidewall of the channels. According to the fin-structured MOS transistor, the gate electrode is formed on both sidewalls of the channel fin, and the gate may be under a control at both sidewalls thereof, thereby reducing the short channel effect. However, the fin-structured MOS transistor is disadvantageous in that because a plurality of channel fins is arranged in parallel along a width direction of the gate, thus the channel region and the source/drain regions are enlarged in the MOS transistor. In addition, the fin-structured MOS transistor also has also problem that a junction capacitance between the source and drain regions is increased as the channel number is increased.

The fully depleted lean-channel structured MOS transistor is exemplarily disclosed in U.S. Pat. No. 4,996,574. According to the fully depleted lean-channel structured MOS transistor, an active layer on which a channel is formed is protruded in a vertical direction with a predetermined width, and a gate electrode surrounds the protruded channel region. Thus, a protruded height corresponds to a width of the channel, and a protruded width corresponds to a thickness of the channel. Accordingly, both sides of the protruded portion are utilized as a channel in the MOS transistor, thus the channel is twice ate size of the conventional channel in a width, thereby preventing the narrow width effect. In addition, reducing the width of the protruded portion causes an overlap of two depletion areas formed at both side portions of the protruded portion, thereby improving channel conductivity.

However, the fully depleted lean-channel structured MOS transistor has disadvantages as follows. When the fully depleted lean-channel structured MOS transistor is formed on a bulk silicon substrate, the bulk substrate is treated firstly such o that a portion thereof, on which the channel region is to be formed, is protruded and then is then oxidized underwith the condition that the protruded portion of the substrate is covered with an anti-oxidation layer. If in case that the substrate is over oxidized, a ridge portion of the substrate between the protruded portion and a non-protruded or an even portion is also oxidized with oxygen that is laterally diffused from the even portion that is not covered with the anti-oxidation layer, t. Thus the channel on the protruded portion of the substrate is separated from the even portion of the substrate. That is, an over-oxidation separates the channel from the bulk substrate, and reduces a thickness of the ridge portion of the substrate. In addition, a single-crystalline layer is damaged due to a stress during the over-oxidation process.

When the fully depleted lean-channel structured MOS transistor is formed on a silicon-on-insulator (SOI) substrate, the SOI layer on the substrate is etched away to thereby form a channel region having a narrow width. Therefore, in contrast to the bulk substrate, the over-oxidation gives rise to no problem when the SOI substrate is utilized. However, there is a problem in the fully depleted lean-channel structured MOS transistor formed on the SOI substrate in that the channel width is restricted within the thickness of the SOI layer. In particular, in the case of a fully depletioned type SOI substrate, the SOI thickness on the substrate is at most a few hundred angstroms (Å), thus the channel width is considerably restricted by the SOI thickness.

A gate-all-around MOS transistor (GAA MOS transistor) is disclosed in U.S. Pat. No. 5,497,019. According to the GAA MOS transistor, an active pattern is formed on the SOI layer and a gate insulation layer is formed on a whole surface of the active pattern. A channel region is formed on the active pattern and the gate electrode surrounds the channel region. Thus the narrow width effect is prevented and the channel conductivity is improved similarly to the fully depleted lean-channel structured MOS transistor.

However, the GAA MOS transistor also has also problems, as follows. When the gate electrode surrounds the active pattern corresponding to the channel region, a buried oxide layer underlying the active pattern on the SOI layer needs to be etched using an under-cut phenomenon during the etching process. However, since the SOI layer is utilized as a source/drain region as well as the channel region, the isotropic etching process removes the source/drain region as well as a lower portion of the channel region. Therefore, when a conductive layer is formed on the channel region for the gate electrode, the gate electrode is formed on the source/drain regions as well as the channel region. Thus, there is a problem in that a parasitic capacitance is increased in the GAA MOS transistor.

In addition, a lower portion of the channel region is horizontally etched away during the isotropic etching process, so that a horizontal length (or a width) of a tunnel that is to be buried by the gate electrode in a subsequent process is increased. That is, according to the GAA MOS transistor, the gate length is hardly reduced below the width of the channel.

Embodiments of the invention address these and other disadvantages of the conventional art.

### SUMMARY OF THE INVENTION

Embodiments of the invention provide a gate structure of a semiconductor device for effectively preventing a short channel effect or a narrow width effect.

Embodiments of the invention also provide a semiconductor having the above-mentioned gate structure.

Embodiments of the invention further provide a method of forming the above-mentioned gate structure.

Embodiments of the preset invention further still provides a method of manufacturing a semiconductor device having the above-mentioned gate structure.

### BRIEF DESCRIPTION OF THE DRAWINGS

The above and other embodiments and advantages of the present invention will become readily apparent by reference to the following detailed description when considering in conjunction with the accompanying drawings, in which:

FIGS. 1A to 1I are cross sectional views illustrating processing steps of forming a gate structure according to an embodiment of the present invention;

FIG. 2 is a perspective view of the gate structure in accordance with FIGS. 1A to 1I;

FIGS. 3A to 3E are cross sectional views illustrating processing steps of forming a gate structure according to another embodiment of the present invention;

FIG. 4 is a perspective view of the gate structure according to the an embodiment of the present invention;

FIGS. 5A to 5D are cross sectional views illustrating processing steps of forming a gate structure according to yet another embodiment of the present invention;

FIGS. 6A to 6F are cross sectional views illustrating processing steps of forming a gate structure according to still another embodiment of the present invention;

FIG. 7A is a cross sectional view of a modified gate structure according to the first described embodiment of the present invention;

FIG. 7B is a cross sectional view of a modified gate structure according to the fourth described embodiment of the present invention;

FIGS. 8A to 8Z are cross sectional views illustrating processing steps of manufacturing a semiconductor device such as a MOS transistor according to the first described embodiment of the present invention;

FIG. 9 is a perspective view of the MOS transistor formed by the processing steps illustrated in FIGS. 8A to 8Z;

FIG. 10 is a perspective view of a first modified MOS transistor based on the MOS transistor shown in FIG. 9;

FIG. 11A is a perspective view of a second modified MOS transistor based on the MOS transistor shown in FIG. 9;

FIG. 11B is a cross sectional view of the second modified MOS transistor shown in FIG. 11A;

FIG. 12 is a perspective view of a third modified MOS transistor based on the MOS transistor shown in FIG. 9;

FIG. 13 is a perspective view of another third modified MOS transistor based on the MOS transistor shown in FIG. 9;

FIGS. 14A to 14K are cross sectional views illustrating processing steps of manufacturing a semiconductor device according to the second described embodiment of the present invention;

FIGS. 15A to 15E are cross sectional views illustrating processing steps of manufacturing a semiconductor device according to the third described embodiment of the present invention;

FIGS. 16A to 16E are cross sectional views illustrating processing steps of manufacturing a semiconductor device according to the fourth described embodiment of the present invention; and

FIGS. 17A to 17F are cross sectional views illustrating processing steps of manufacturing a semiconductor device according to the fifth described embodiment of the present invention.

### DESCRIPTION OF THE EMBODIMENTS

The present invention now will be described more fully hereinafter with reference to the accompanying drawings in which exemplary embodiments of the present invention are shown.

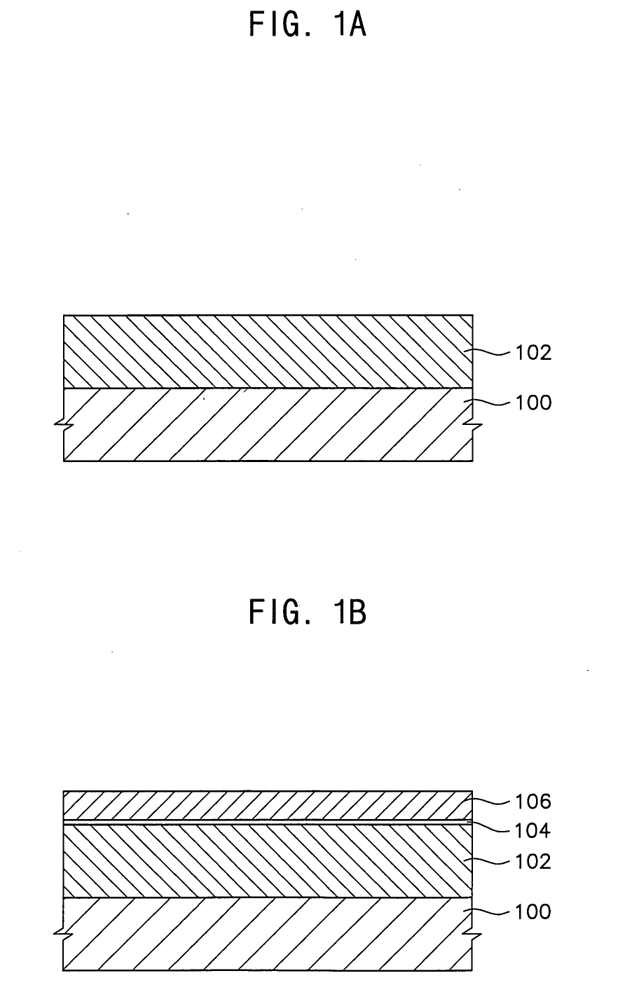

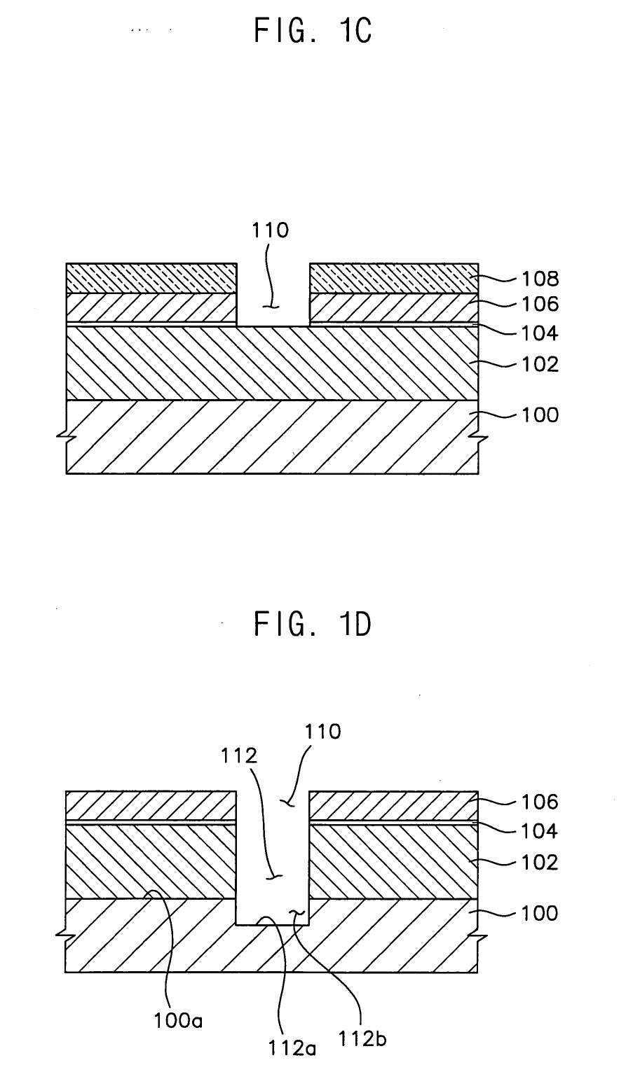

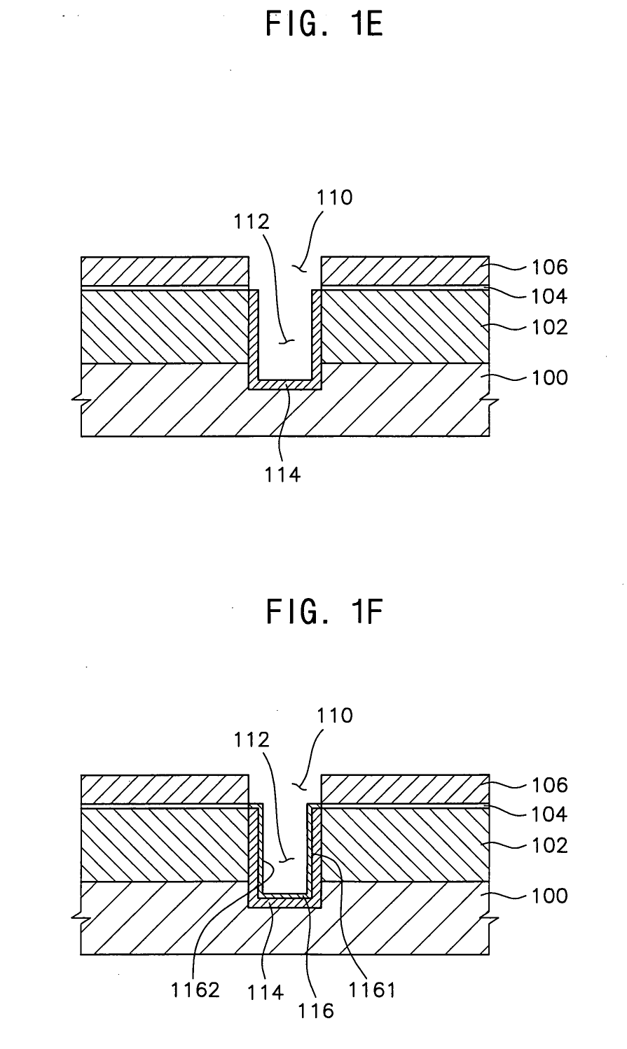

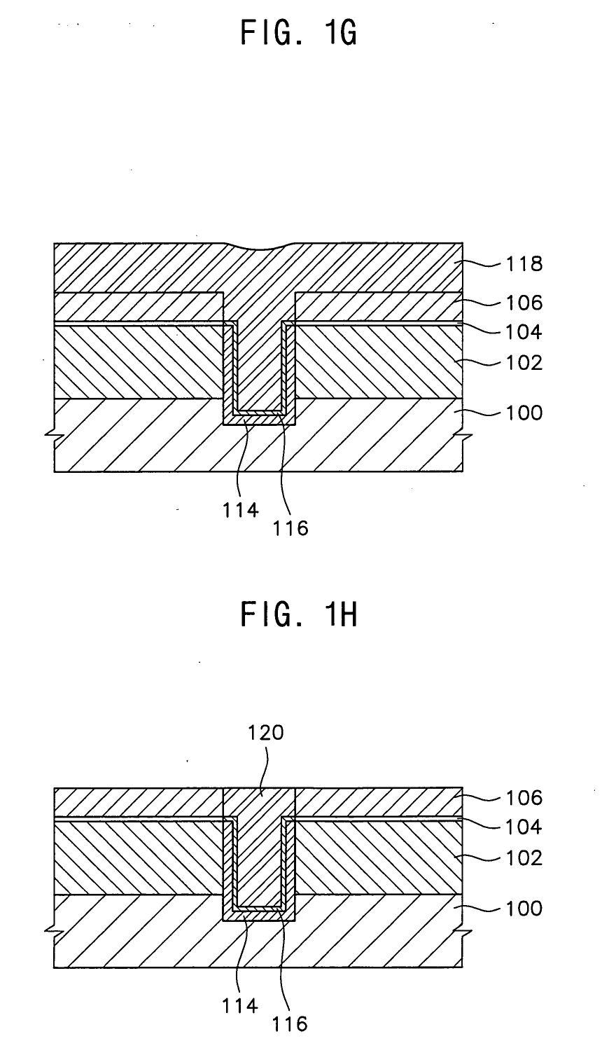

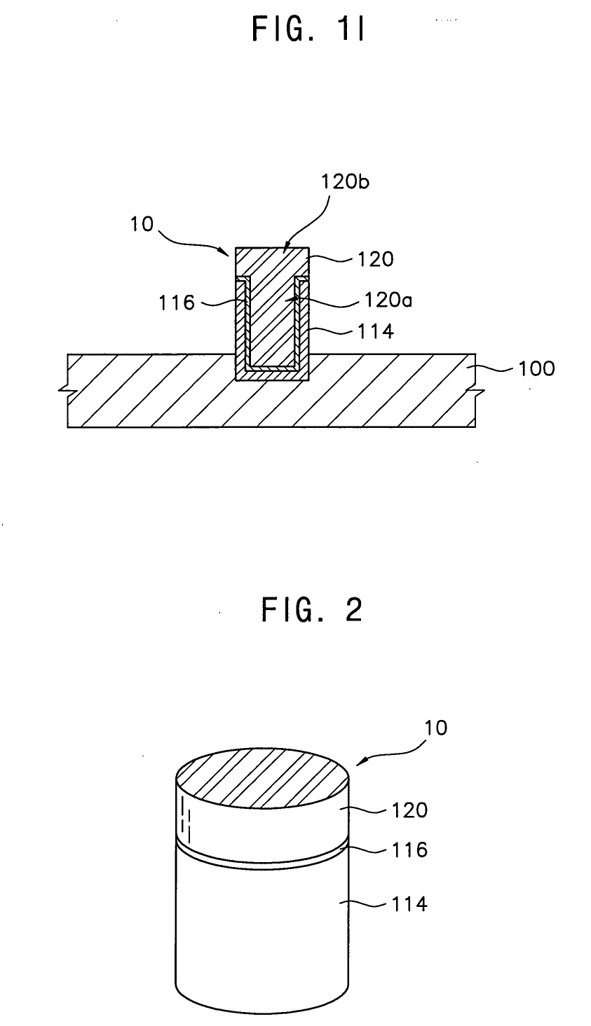

FIGS. 1A to 1I are cross sectional views illustrating processing steps of forming a gate structure according to an embodiment of the present invention, and FIG. 2 is a perspective view of the gate structure in accordance with FIGS. 1A to 1I.

Referring to FIG. 1A, a sacrificial layer 102 is formed on a semiconductor substrate 100 such as a silicon wafer. The sacrificial layer 102 exemplarily comprises silicon germanium, and is formed by a chemical vaporization deposition (CVD) process or an epitaxial growth process. In particular, an ultra high vacuum CVD (UVCVD) process or a low pressure CVD (LPCVD) is usually used for forming the sacrificial layer 102 using a silicon source gas such as silane gas (SiH₄), a germanium source gas such as germanium hydride (GeH₄), and a carrier gas such as hydrogen (H₂) gas. Alternatively, a gas source molecular beam epitaxial (GS-MBE) process may be utilized for forming the sacrificial layer 102.

Referring to FIG. 1B, a buffer oxide layer 104 and a capping layer 106 are sequentially formed on the sacrificial layer 102. The capping layer 106 exemplarily comprises silicon nitride, and is formed by the LPCVD process or a plasma enhanced CVD (PECVD) process using dichlorosilane (SiH₂Cl₂) gas, mono-silane (SiH₄) gas and ammonia gas (NH₃). A heat oxidation process or the CVD process may be utilized for forming the buffer oxide layer 104.

Referring to FIG. 1C, a photoresist pattern 108 for partially exposing the sacrificial layer 102 is formed on the capping layer 106 by a conventional photolithography process, and the capping layer 106 and the buffer oxide layer 104 are etched away using the photoresist pattern as an etching mask, thereby forming a second opening 110 through which the sacrificial layer 102 is partially exposed. For example, the second opening 110 is formed by a plasma etching process or a reactive ion etching process using the photoresist pattern 108 as an etching mask.

Referring to FIG. 1D, the photoresist pattern 108 is removed using a conventional ashing process or a stripping process, and the sacrificial layer 102 is partially etched away using the capping layer 106 as an etching mask, thereby forming a first opening 112 through which the substrate 100 is partially exposed. A portion of the substrate 100 is also etched away during the etching process for forming the first opening 112, so that a bottom surface 112a of the first opening 112 is lower than a surface 100a of the substrate 100. That is, the substrate includes a recessed portion 112b on a top surface thereof, and the first opening 112 includes a recessed portion 112b of the substrate 100. Therefore, a bottom surface of the recessed portion 112b corresponds to the bottom surface 112a of the first opening 112. For example, an etching time for forming the first opening 112 is prolonged, thus a surface portion of the substrate 100 is over-etched away during the formation of the first opening 112.

Referring to FIG. 1E, a single-crystalline silicon layer is formed on an inner surface of the first opening 112 with a uniform thickness, thereby forming a single-crystalline silicon pattern 114. Accordingly, the single-crystalline silicon pattern 114 has a cylindrical shape of which a top portion is open. For example, the single-crystalline silicon pattern 114 may be formed by a selective epitaxial process using silicon source gas. That is, the single-crystalline silicon pattern 114 grows from the substrate 100 and the sacrificial layer 102 including silicon by the selective epitaxial process, thus the single-crystalline silicon pattern 114 grows only along the inner side surface of the first opening 112. That is, the single-crystalline silicon pattern 114 is formed on a bottom surface and an inner side surface of the first opening 112. Accordingly, the single-crystalline silicon pattern 114 is not formed on a top surface of the capping layer 106 and on an inner side surface of the second opening 110. The single-crystalline silicon pattern 114 is exemplarily formed to a thickness of about 100 Å to about 300 Å.

Referring to FIG. 1F, a gate insulation layer 116 is formed on a top surface and on an inner surface of the single-crystalline silicon pattern 114, so that the single-crystalline silicon pattern 114 is covered with the gate insulation layer 116. That is, the gate insulation layer 116 has a cylindrical shape in accordance with the single-crystalline silicon pattern 114, and thus an outer surface of the gate insulation layer 116 makes contact with the top surface and the inner surface of the single-crystalline silicon pattern 114 and an inner surface of the gate insulation layer 116 encloses a space defined by the first opening 112. The gate insulation layer 116 may exemplarily comprise silicon oxide layer or a silicon oxynitride layer, and be formed to a thickness of about 10 Å to 70 Å by a rapid thermal process (RTP) using oxygen (O₂) gas, nitrogen monoxide (NO) gas, or nitrous oxide (N₂O) gas.

Referring to FIG. 1G, a conductive layer 118 is formed on the capping layer 106 to a sufficient thickness so that the space defined by the second opening 110 and the first opening 112, limited by the gate insulation layer 116, are covered with the conductive layer 118. The conductive layer 118 may comprise a doped polysilicon. In particular, a polysilicon layer is formed by an LPCVD process, and impurities are in-situ doped into the polysilicon layer.

According to another embodiment of the present invention, a polysilicon layer is formed to fill up the spaces defined by the second opening 110 and the first opening 112, limited by the gate insulation layer 116, by using an LPCVD process, and the polysilicon layer is transformed into a conductive layer by an impurity doping process. The impurity doping process may be a conventional ion implantation process or an impurity diffusion process.

According to another embodiment of the present invention, the conductive layer 118 may comprise a metal. Examples of the metal include tungsten, titanium, tantalum, cobalt, nickel, molybdenum, ruthenium, etc. These can be used alone or a in combination thereof. As an exemplary embodiment, the metal conductive layer 118 may be formed by a deposition process using a metal precursor such as a metal organic chemical vapor deposition (MOCVD) process, a physical vapor deposition (PVD) process, or an atomic layer deposition (ALD) process.

Referring to FIG. 1H, the conductive layer 118 is planarized and removed by using an etch-back process or a chemical mechanical polishing (CMP) process until a top surface of the capping layer 106 is exposed. Therefore, the conductive layer 118 remains only inside the first and second openings 112 and 110, thereby forming a gate electrode 120.

Referring to FIGS. 1I and 2, the capping layer 106, the buffer oxide layer 104 and the sacrificial layer 102 are completely removed from the substrate 100 by a conventional dry and wet etching process. For example, the capping layer 106 and the buffer oxide layer 104 are removed by a dry etching process, and the sacrificial layer 102 is removed by a wet etching process using an etchant in which an etching selectivity of the sacrificial layer 102 with respect to the silicon germanium and the single-crystalline silicon is no less than about 50:1.

As shown in FIGS. 1I and 2, the gate structure 10 according to the present embodiment has a pillar shape as a whole, and a lower portion of the gate structure 10 is formed on the recessed portion of the substrate 100. In addition, the gate structure 10 includes the gate electrode 120 protruded from the substrate 100 in a vertical direction, and the gate insulation layer 116 enclosing a side surface of the gate electrode 120.

In particular, the gate electrode 120 includes a first pillar 120a having a first diameter and a second pillar 120b that is formed on a top surface of the first pillar 120a and has a second diameter larger than the first diameter. As an exemplary embodiment, the first and second pillars are integrally formed with each other during the deposition process for forming the conductive layer 118. The gate insulation layer 116 makes contact with a side surface and a bottom surface of the first pillar 120a and a bottom surface of the second pillar 120b.

A channel region of a MOS transistor (not shown) including the above-mentioned gate structure 10 is formed on the single-crystalline silicon pattern 114 that makes contact with the gate insulation layer 116. In particular, when source/drain regions of the MOS transistor are formed on upper and lower portions of the gate structure 10, respectively, the channel region of the MOS transistor is formed at a central portion of the single-crystalline silicon pattern 114 having a shape of a pillar ring or a circular tube.

Accordingly, a channel length of the MOS transistor is determined by a height of the gate insulation layer 116, and a channel width of the MOS transistor is also determined by an outer diameter of the gate insulation layer 116. That is, the channel length of the MOS transistor may be determined by a thickness of the sacrificial layer 102, and the channel width of the MOS transistor may be also determined both by an inner diameter of the second opening 112 and by the thickness of the single-crystalline silicon pattern 114.

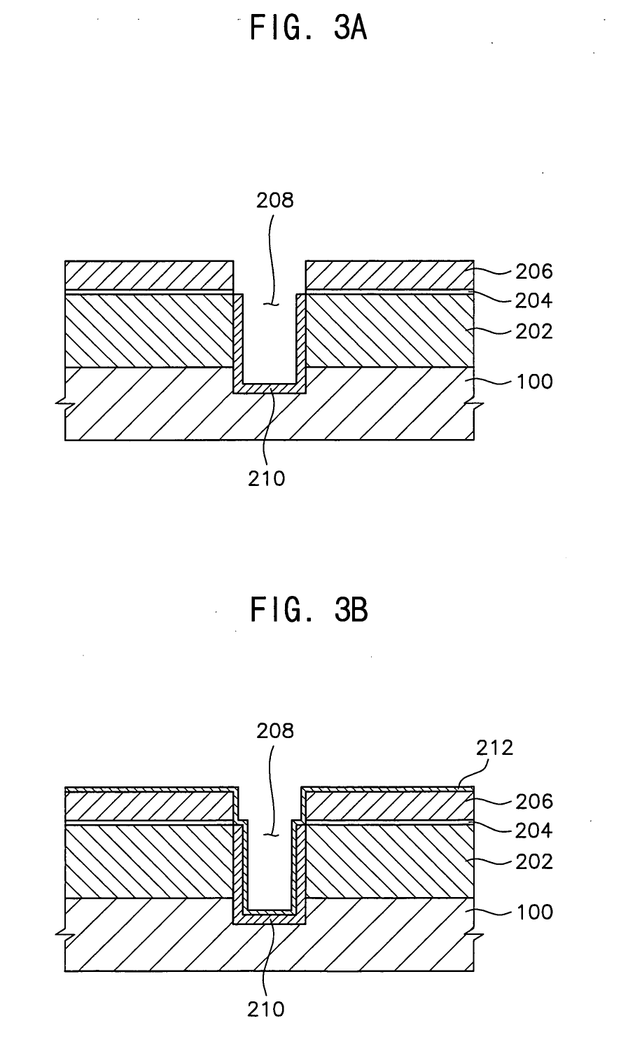

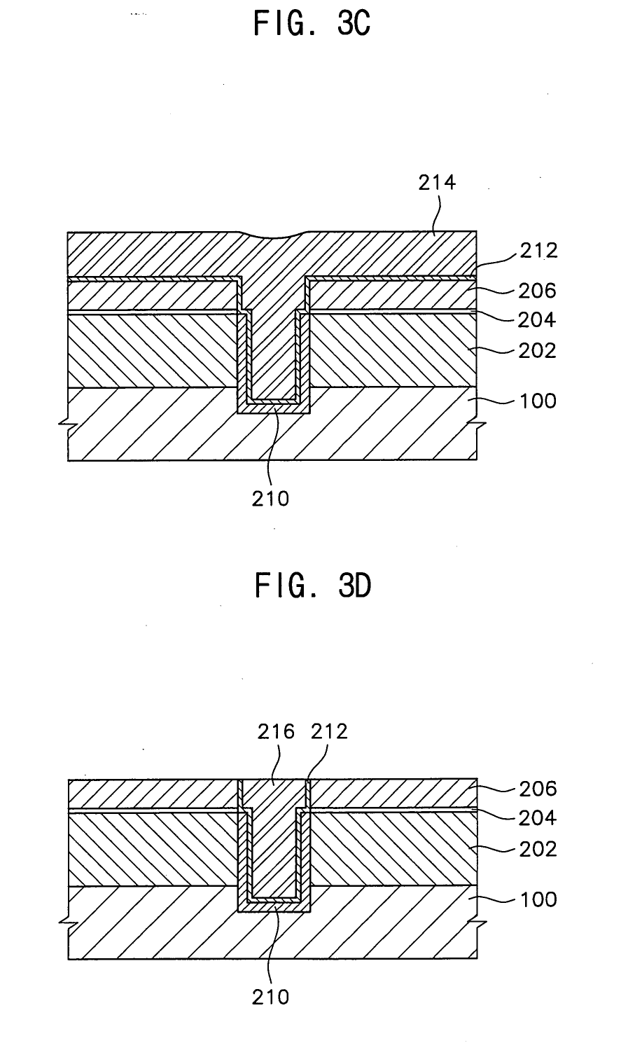

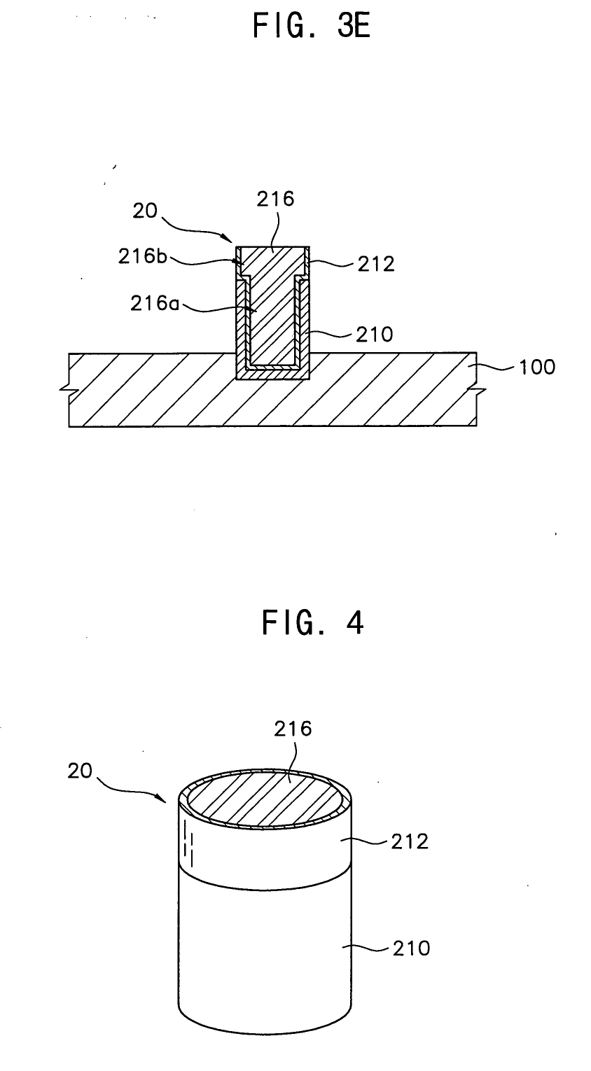

FIGS. 3A to 3E are cross sectional views illustrating processing steps of forming a gate structure according to another embodiment of the present invention, and FIG. 4 is a perspective view of the gate structure formed by the processing steps in accordance with FIGS. 3A to 3E.

Referring to FIG. 3A, an opening 208 crossing a sacrificial layer 202, a buffer oxide layer 204 and a capping layer 206 is formed on a substrate 100, and a single-crystalline silicon layer is formed on a surface of the substrate 100 and an inner side surface of the sacrificial layer 202, thereby forming a single-crystalline pattern 210 in the opening 208. Accordingly, the single-crystalline silicon pattern 210 partially encloses a space defined by the opening 208. As an exemplarily embodiment, the single-crystalline silicon pattern 210 and the opening 208 are formed by the same method as described with reference to FIGS. 1A to 1E.

Referring to FIG. 3B, a gate insulation layer 212 is formed on a top surface of the capping layer 206 and on an inner surface of the opening 208, so that the gate insulation layer 212 is formed on the top surface and a side surface of the capping layer 206 and on side and bottom surfaces of the single-crystalline silicon pattern 210. As an exemplary embodiment, the gate insulation layer 212 may be a silicon oxide layer, a silicon oxynitride layer, a metal oxide layer, or a composite layer thereof. The silicon oxide layer and the silicon oxynitride layer may be formed by the LPCVD process, and the metal oxide layer may be formed by the MOCVD or ALD process. Examples of the metal oxide include a tantalum oxide (Ta₂O₅) layer, a tantalum oxynitride (TaON) layer, a titanium oxide (TiO₂) layer, an aluminum oxide (Al₂O₃) layer, a yttrium oxide (Y₂O₃) layer, a zirconium oxide (ZrO₂) layer, a hafnium oxide (HfO₂) layer, a barium titanate oxide (BaTiO₃) layer, a strontium titanate oxide (SrTiO₃) layer, etc. These can be used alone or in a combination thereof (as a composite layer including at least two among them).

Referring to FIG. 3C, a conductive layer 214 is formed on the gate insulation layer 212 to a sufficient thickness so that the opening 208 is covered with the conductive layer 214 comprising doped polysilicon or metal. The conductive layer comprising the doped polysilicon may be formed by a consecutive process of the LPCVD and doping of the impurities. In addition, the conductive layer comprising the metal may be formed by the MOCVD and the ALD processes. Examples of the metal layer include a tungsten layer, a titanium layer, a tantalum layer, a cobalt layer, a molybdenum layer, a nickel layer, a ruthenium layer, etc. These can be used as a single layer or a composite layer thereof.

Referring to FIG. 3D, the conductive layer 214 is removed for forming a gate electrode 216. The conductive layer 214 and the gate insulation layer 212 are planarized and removed by an etch-back process or a CMP process until a top surface of the capping layer 206 is exposed, and thus the conductive layer 214 only remains in the opening 208, and makes contact with the gate insulation silicon layer 212, thereby forming the gate electrode 216.

Referring to FIGS. 3E and 4, the capping layer 206, the buffer oxide layer 204 and the sacrificial layer 202 are completely removed from the substrate 100 by a conventional dry and wet etching process. For example, the capping layer 206 and the buffer oxide layer 204 are removed by a dry etching process, and the sacrificial layer 202 is removed by a wet etching process using an etchant in which an etching selectivity of the sacrificial layer 202 with respect to the silicon germanium and the single-crystalline silicon is no less than about 50:1.

As shown in FIGS. 3E and 4, the gate structure 20 according to the present embodiment has a pillar shape as a whole, and a lower portion of the gate structure 20 is also formed into a recessed portion of the substrate 100 in a similar way to the previous embodiment. In addition, the gate structure 20 includes the gate electrode 120 protruded from the substrate 100 in a vertical direction, and the gate insulation layer 212 enclosing the gate electrode 120.

In particular, the gate electrode 216 includes a first pillar 216a having a first diameter and a second pillar 216b that is disposed on a top surface of the first pillar 216a and has a second diameter larger than the first diameter. As an exemplary embodiment, the first and second pillars 216a and 216b are integrally formed in a body during the deposition process for forming the conductive layer 214. The gate insulation layer 212 makes contact with all of the outer surfaces of the gate electrode 216 only except for a top surface thereof.

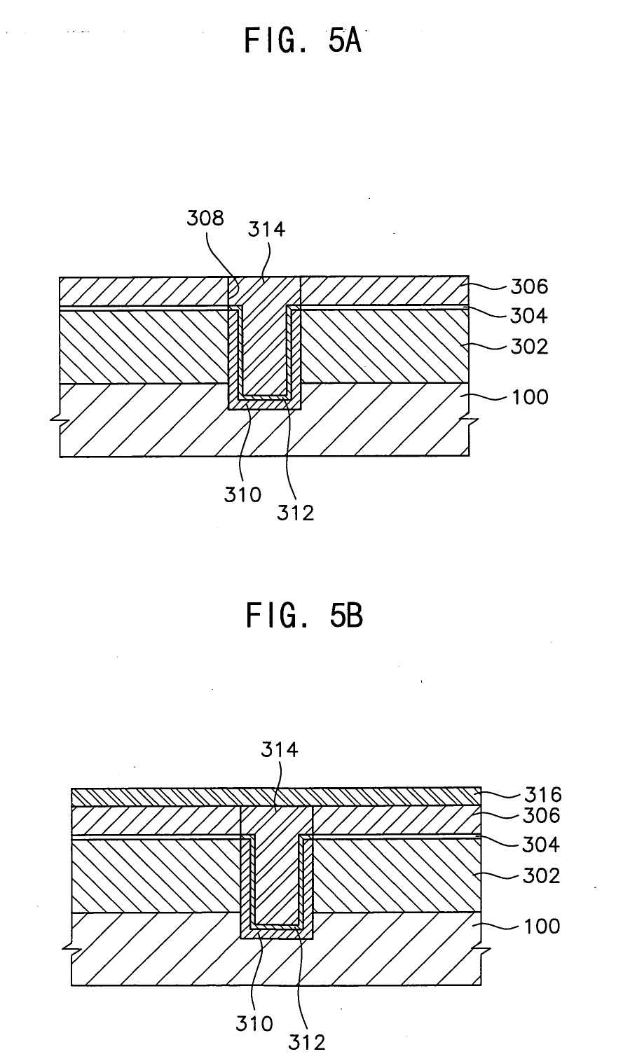

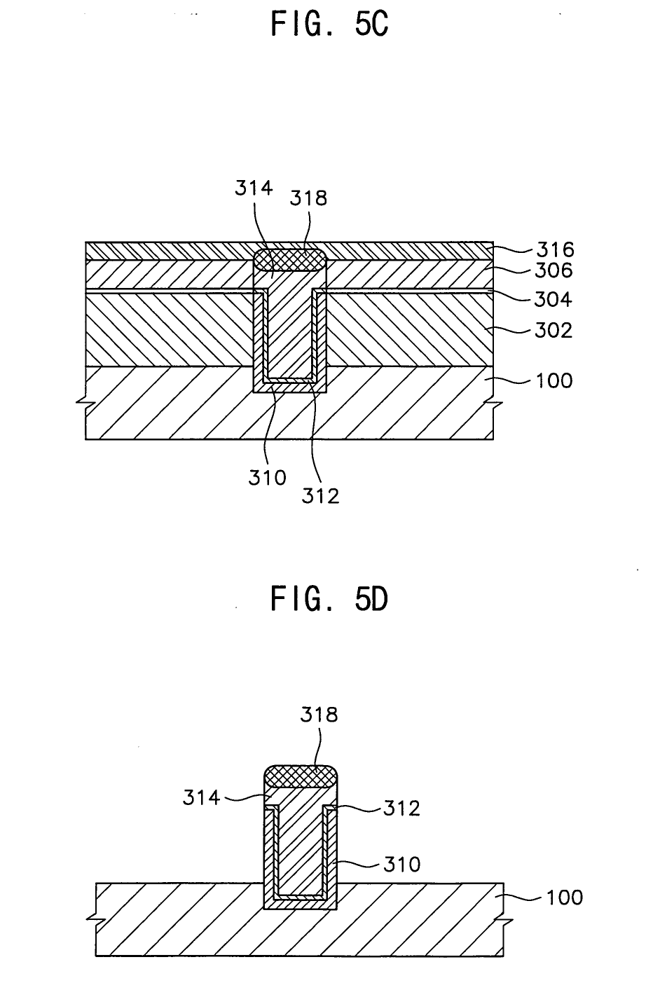

FIGS. 5A to 5D are cross sectional views illustrating processing steps of forming a gate structure according to yet another embodiment of the present invention.

Referring to FIG. 5A, an opening 308 crossing a sacrificial layer 302, a buffer oxide layer 304 and a capping layer 306 is formed on a substrate 100, and a single-crystalline silicon layer is formed on a surface of the substrate 100 and an inner side surface of the sacrificial layer 302, thereby forming a single-crystalline pattern 310 in the opening 308. A gate insulation layer 312 is formed on side and bottom surfaces of the single-crystalline silicon pattern 310, and the opening 308 is filled with a conductive material to thereby form a gate electrode 314. The single-crystalline pattern 310, the gate insulation layer 312 and the gate electrode 314 are formed in a similar manner described with reference to FIGS. 1A to 1H or FIGS. 3A to 3D.

Referring to FIG. 5B, a metal layer 316 is formed on the capping layer 306 and the gate electrode 314. The metal layer may be formed by the MOCVD and the ALD process. Examples of the metal layer include a tungsten layer, a titanium layer, a tantalum layer, a cobalt layer, a molybdenum layer, a nickel layer, a ruthenium layer, etc.

Referring to FIG. 5C, a heat treatment is performed on the substrate including the metal layer 316, thus the metal layer 316 is reacted with the gate electrode 314 comprising the doped polysilicon. Accordingly, a metal silicide layer 318 is formed on a top surface of the polysilicon layer doped with impurities, so that the gate electrode 314 further includes the metal silicide layer 318.

Referring to FIG. 5D, the metal layer 316, the capping layer 306, the buffer oxide layer 304 and the sacrificial layer 302 are completely removed from the substrate 100 by a conventional dry and wet etching process. The metal layer 316 is removed by a wet etching process using an etchant having an etching selectivity thereof with respect to the metal silicide layer 318. The capping layer 306 and the buffer oxide layer 304 are exemplarily removed by a dry etching process, and the sacrificial layer 202 is removed by a wet etching process using an etchant in which an etching selectivity of the sacrificial layer 202 with respect to the silicon germanium and the single-crystalline silicon is no less than about 50:1.

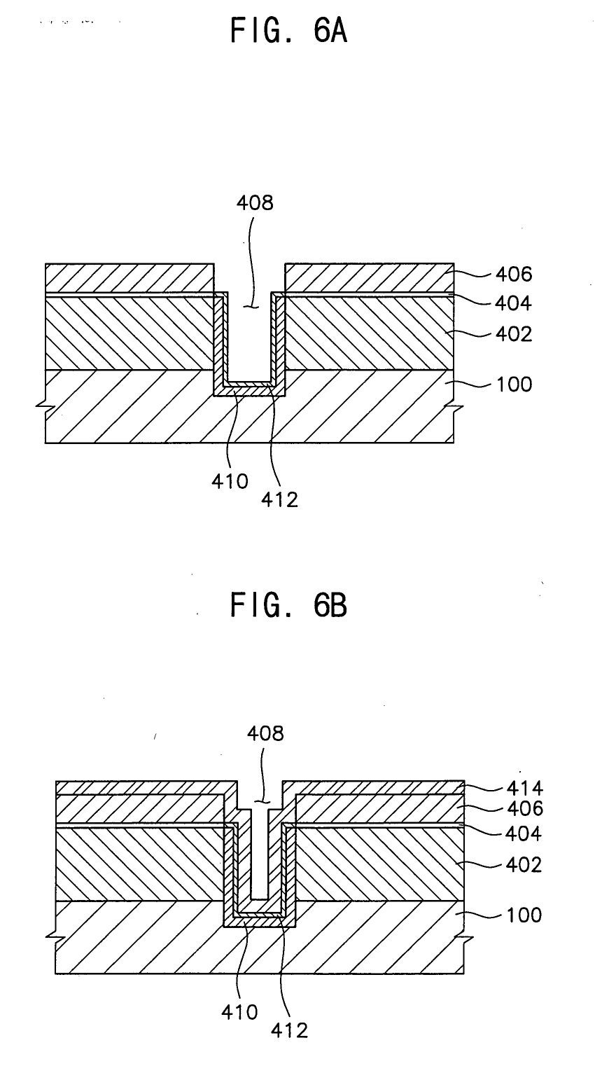

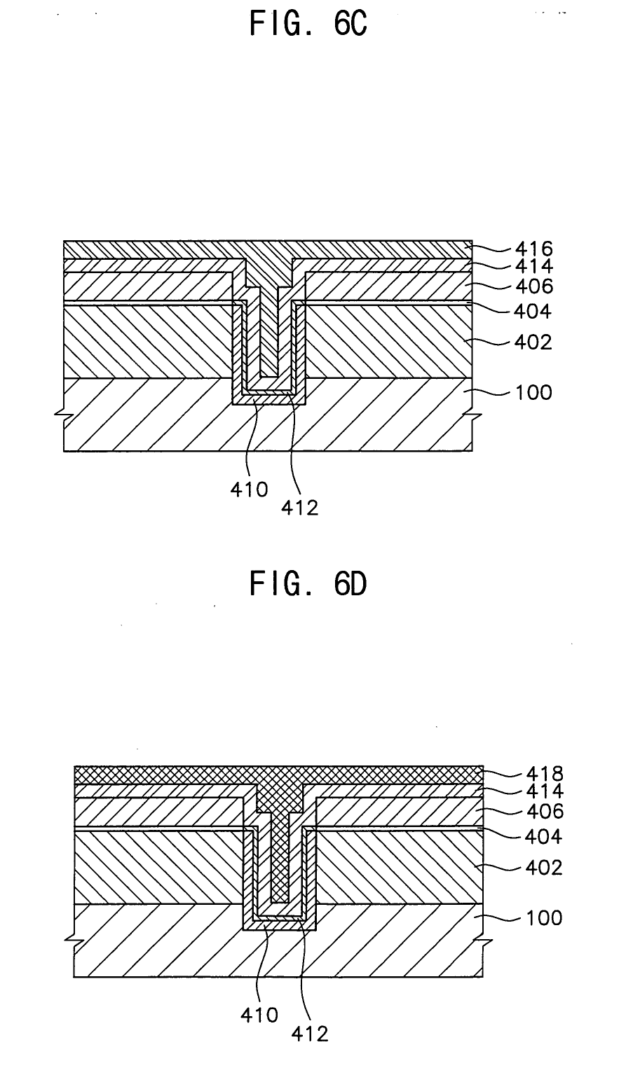

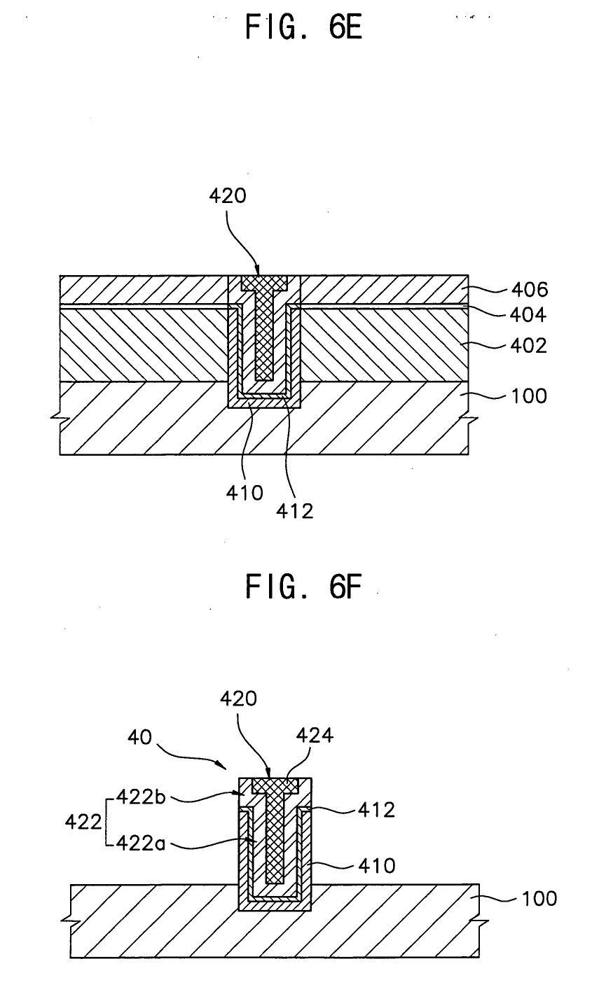

FIGS. 6A to 6F are cross sectional views illustrating processing steps of forming a gate structure according to still another embodiment of the present invention.

Referring to FIG. 6A, an opening 408 crossing a sacrificial layer 402, a buffer oxide layer 404 and a capping layer 406 is formed on a substrate 100, and a single-crystalline silicon layer is formed on a surface of the substrate 100 and an inner side surface of the sacrificial layer 402, thereby forming a single-crystalline pattern 410 in the opening 408. A gate insulation layer 412 is formed on side and bottom surfaces of the single-crystalline silicon pattern 410. The single-crystalline pattern 410 and the gate insulation layer 412 are formed in a similar manner described with reference to FIGS. 1A to IF or FIGS. 3A to 3B.

Referring to FIG. 6B, a conductive layer 414 is formed to have a uniform thickness on the capping layer 406 and on an inner surface of the opening 408. The conductive layer 414 exemplarily comprising doped polysilicon may be formed by a consecutive process of the LPCVD and doping of the impurities.

Referring to FIG. 6C, a metal layer 416 is formed on the conductive layer 414 so that a space defined by the conductive layer 414 in the opening 408 is covered with the metal layer 416. The metal layer may be formed by the MOCVD and the ALD process. Examples of the metal layer include a tungsten layer, a titanium layer, a tantalum layer, a cobalt layer, a molybdenum layer, a nickel layer, a ruthenium layer, etc.

Referring to FIG. 6D, a heat treatment is performed on the substrate 100 including the metal layer 416, thus the metal layer 416 is reacted with the doped polysilicon. Accordingly, the metal layer is transformed into a metal silicide layer 418 due to the heat treatment.

Referring to FIG. 6E, the metal silicide layer 418 and the conductive layer 414 are removed for forming a gate electrode 420. The metal silidice layer 418 and the conductive layer 414 are planarized and removed by an etch-back process or a CMP process until a top surface of the capping layer 406 is exposed, and thus the metal silidice layer 418 and the conductive layer 414 only remain in the opening 408, and makes contact with the gate insulation silicon layer 412, thereby forming the gate electrode 420.

Referring to FIG. 6F, the capping layer 406, the buffer oxide layer 404 and the sacrificial layer 402 are completely removed from the substrate 100 by a conventional dry and wet etching processes. The wet etching process uses an etchant in which an etching selectivity of the sacrificial layer 402 with respect to the silicon germanium and the single-crystalline silicon is no less than about 50:1.

As described above, the gate structure 40, according to the present embodiment of the invention includes a gate electrode 420 and the gate insulation layer 412.

In particular, the gate electrode 420 includes a conductive pattern 422 and a metal silicide plug 424. The conductive plug includes a first cylinder 422a having a first outer diameter and a second cylinder 422b that is disposed on a top surface of the first cylinder 422a and has a second diameter greater than the first diameter. The metal silicide plug 424 fills inside the conductive pattern 422. The gate insulation layer 412 makes contact with side and bottom surfaces of the first cylinder 422a and a bottom surface of the second cylinder 422b. As an exemplary modification of the present embodiment, the gate insulation layer 412 makes contact with all the outer surfaces except for a top surface of the gate electrode 420.

The gate insulation layer 412 may comprise silicon oxide, silicon oxynitride or metal oxide. Examples of the metal oxide include a tantalum oxide (Ta₂O₅) layer, a tantalum oxynitride (TaON) layer, a titanium oxide (TiO₂) layer, an aluminum oxide (Al₂O₃) layer, a yttrium oxide (Y₂O₃) layer, a zirconium oxide (ZrO₂) layer, a hafnium oxide (HfO₂) layer, a barium titanate oxide (BaTiO₃) layer, a strontium titanate oxide (SrTiO₃) layer, etc.

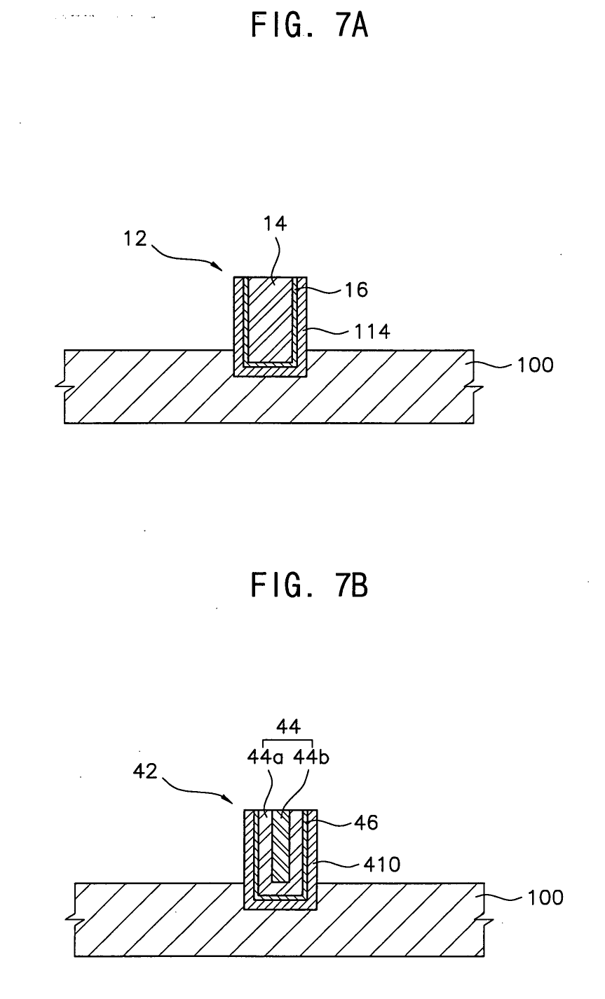

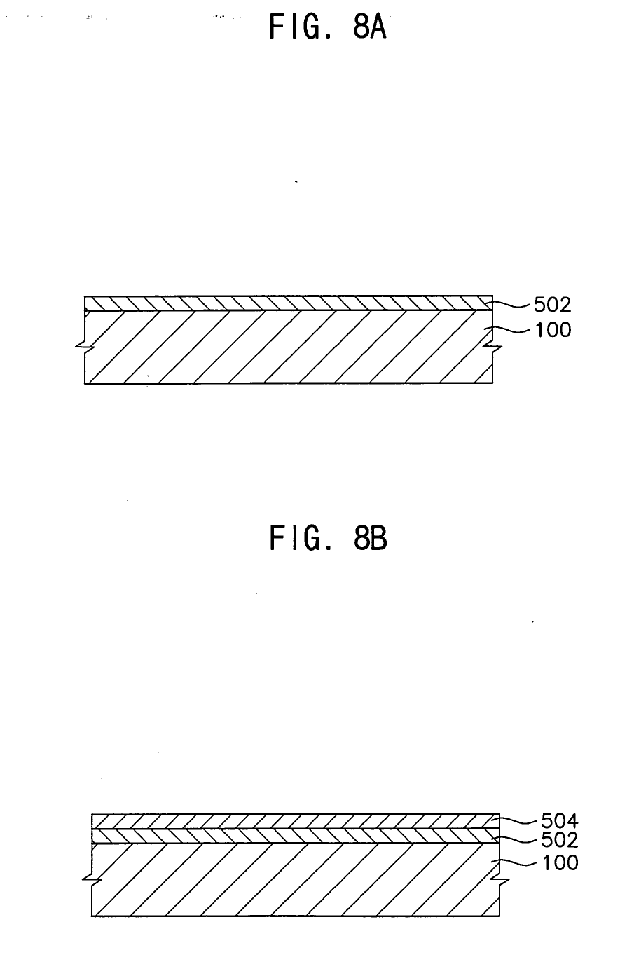

FIG. 7A is a cross sectional view illustrating a modified gate structure according to the first described embodiment of the present invention, and FIG. 7B is a cross sectional view illustrating a modified gate structure according to the fourth described embodiment of the present invention.

Referring to FIG. 7A, in contrast to the first described embodiment of the present invention, the conductive layer 118 in FIG. 1 G may be further planarized and removed until a top surface of the sacrificial layer 102 in FIG. 1H is exposed. Accordingly, the conductive layer 118, the capping layer 106, and the buffer oxide layer 104 are completely removed, and a gate structure 12 includes a gate electrode 14 and a gate insulation layer 16 that encloses the gate electrode 14 and makes contact with a side surface of the gate electrode 14. As an exemplary embodiment, the sacrificial layer 102 is etched away by using a wet etching process.

Referring to FIG. 7B, in contrast to the fourth described embodiment of the present invention, the metal silicide layer 418 and the conductive layer 414 in FIG. 6D may be further planarized and removed until a top surface of the sacrificial layer 402 in FIG. 6E is exposed. Accordingly, the metal silicide layer 418, the conductive layer 414 doped with the polysilicon, the capping layer 406, and the buffer oxide layer 404 are completely removed, and a gate structure 42 includes a gate electrode 14 having a conductive pattern 44a, which is formed into a cylindrical shape and doped with polysilicon, and a metal silicide plug 44b filling the conductive pattern 44a. The gate insulation layer 46 encloses, and is in a contact with, a side surface of the conductive pattern 44.

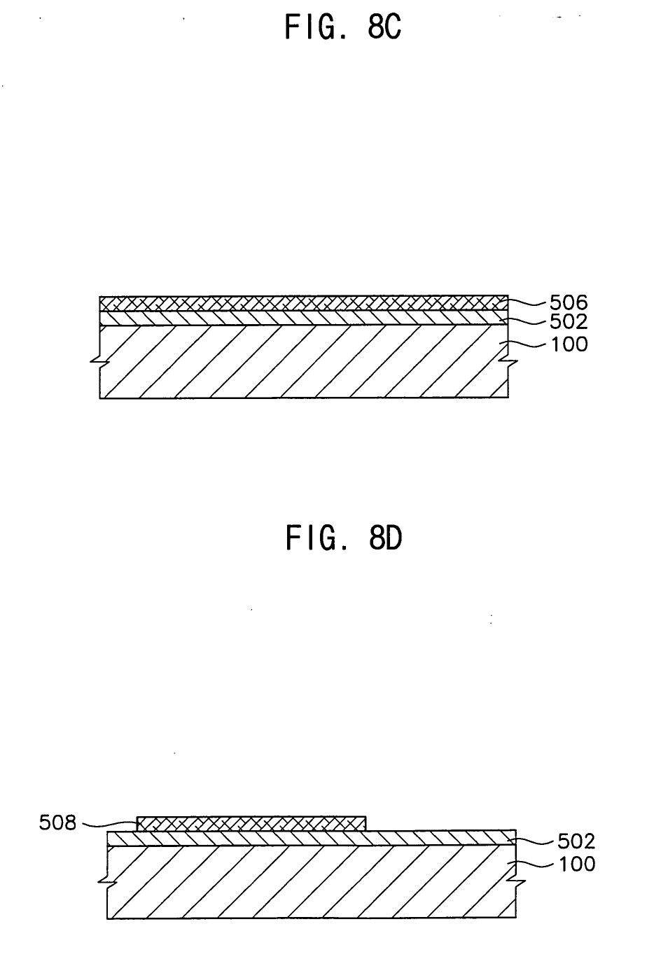

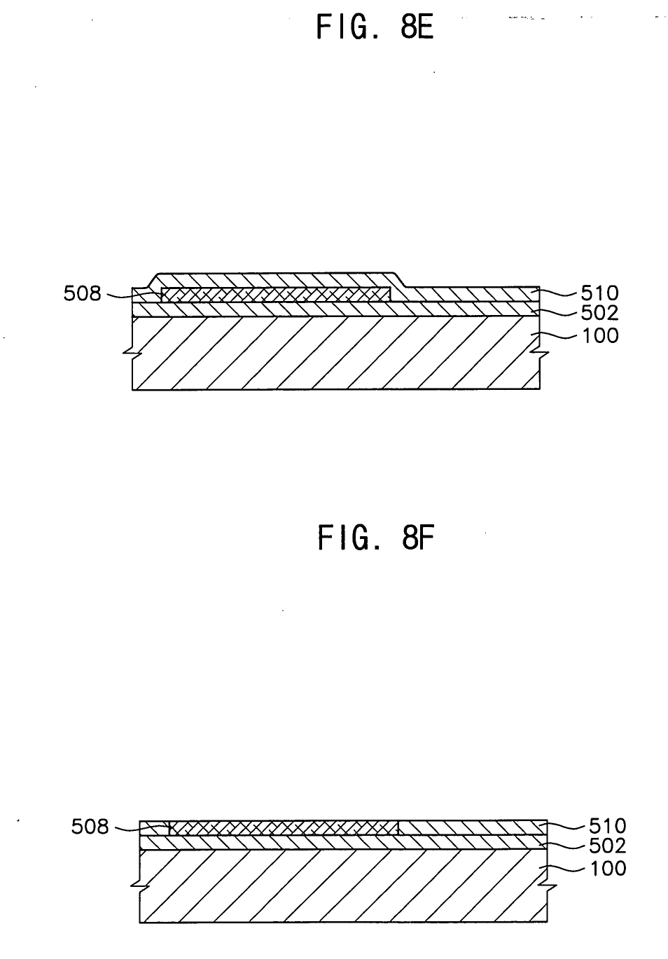

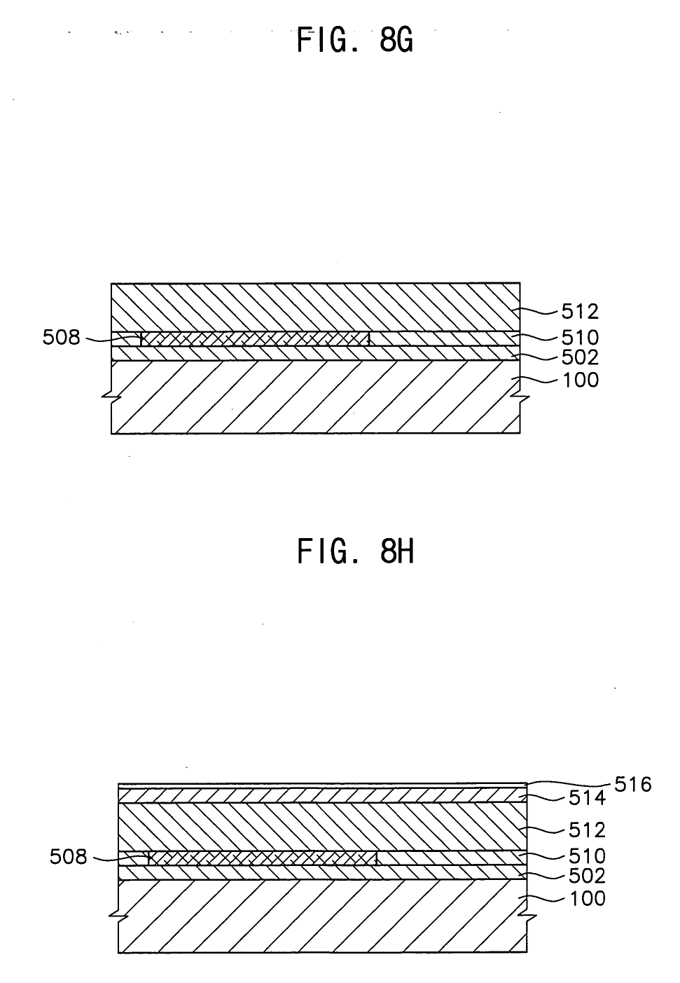

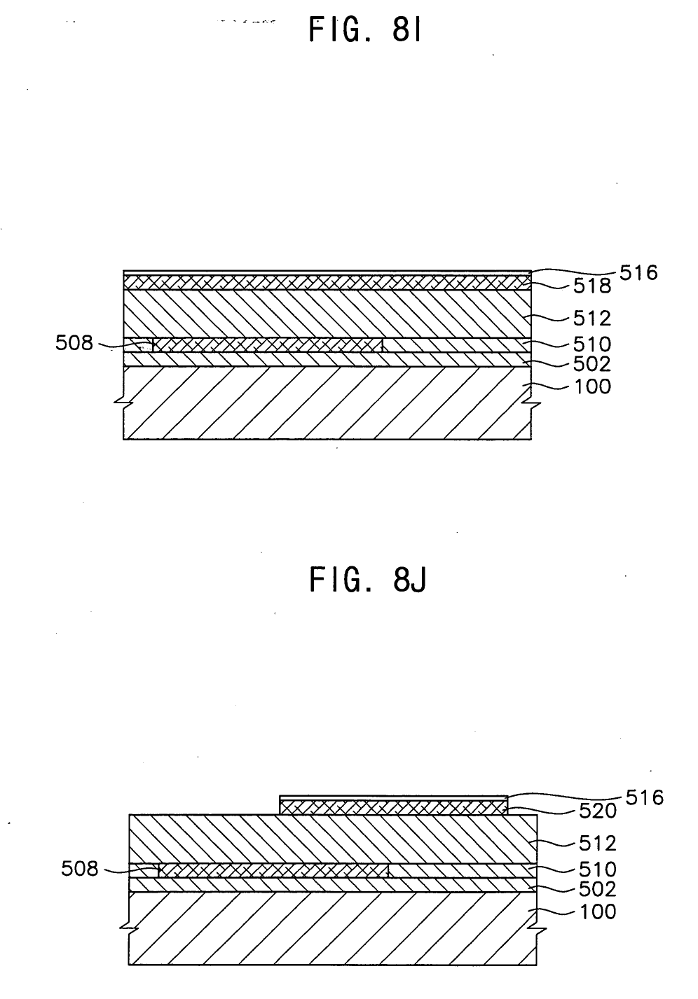

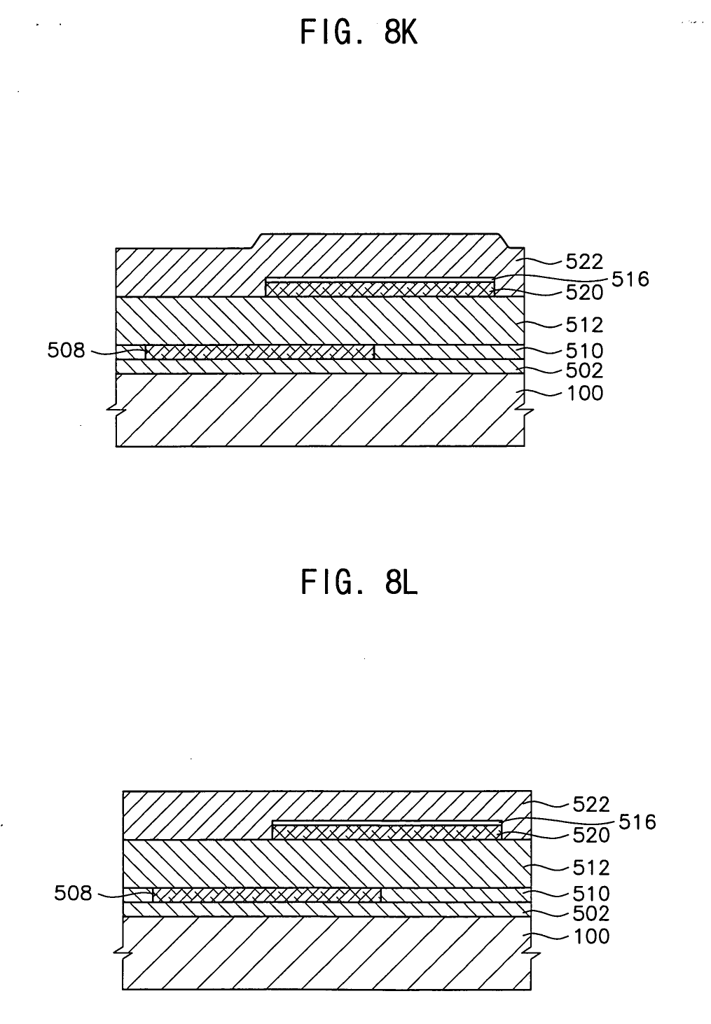

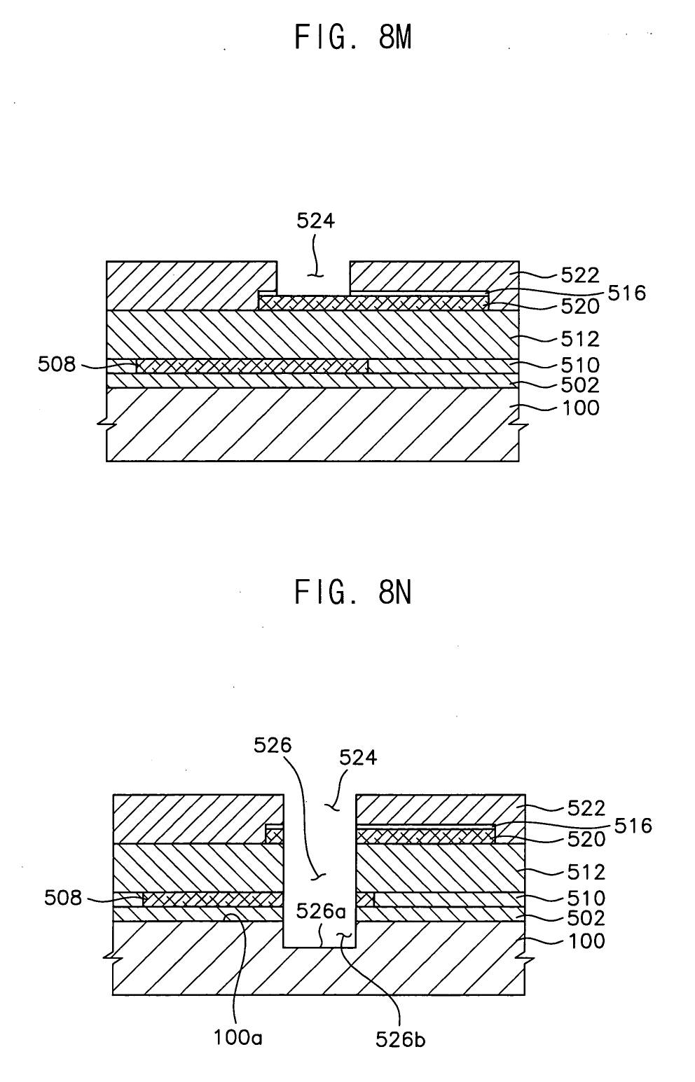

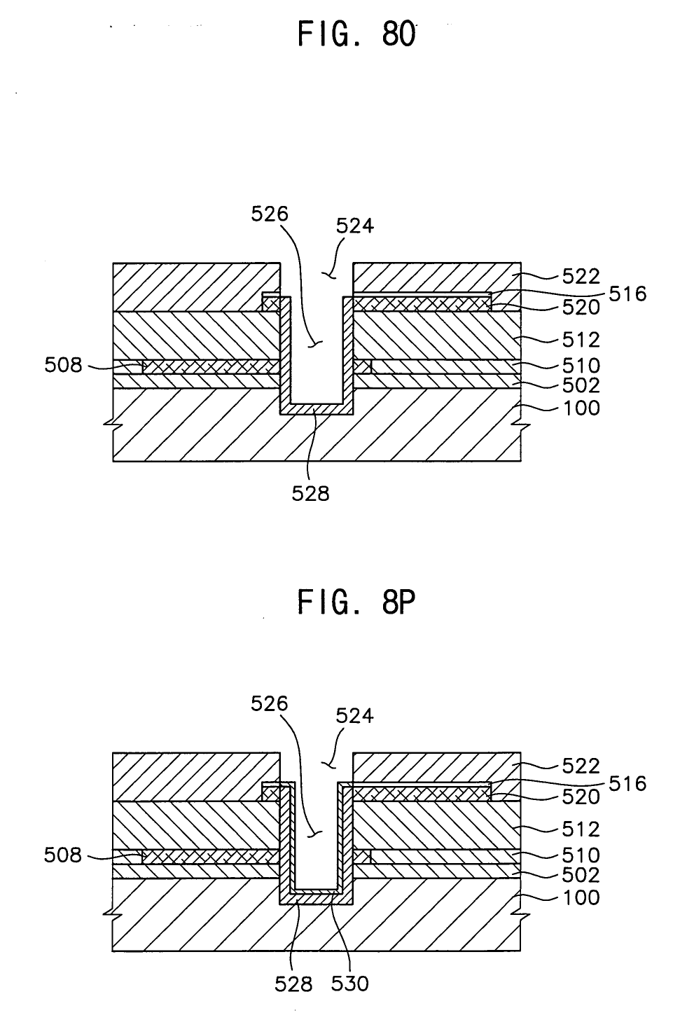

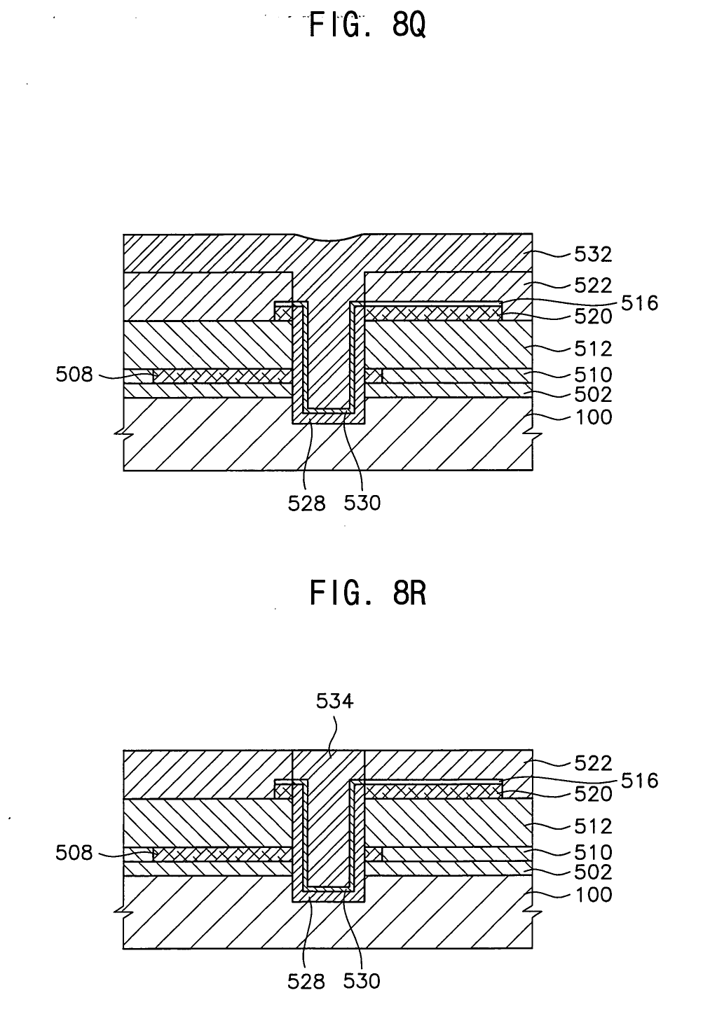

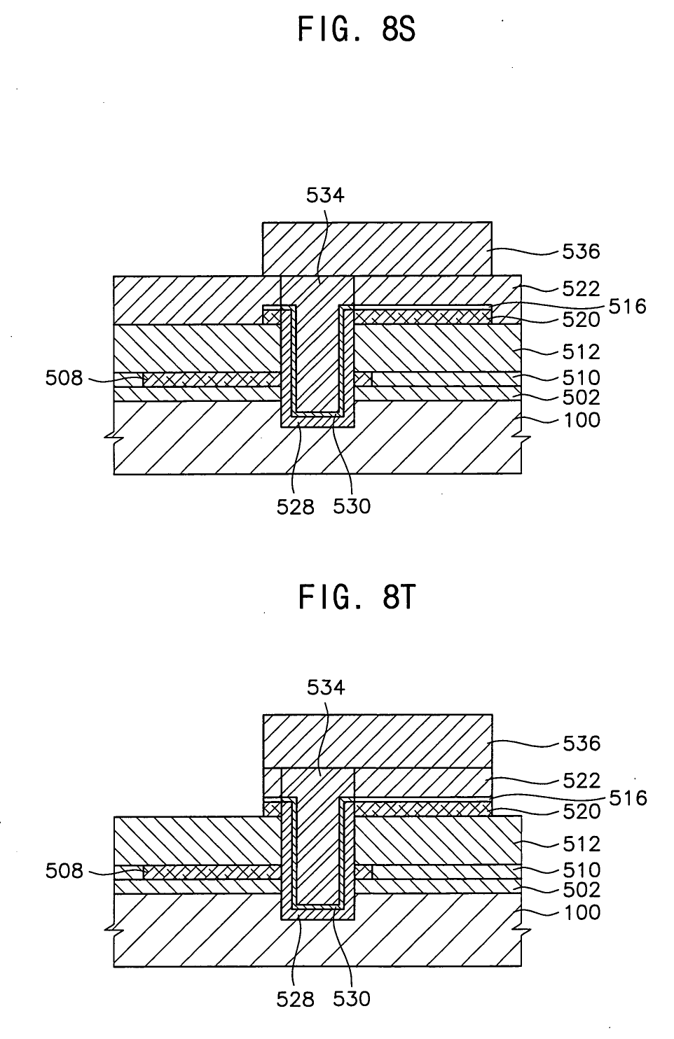

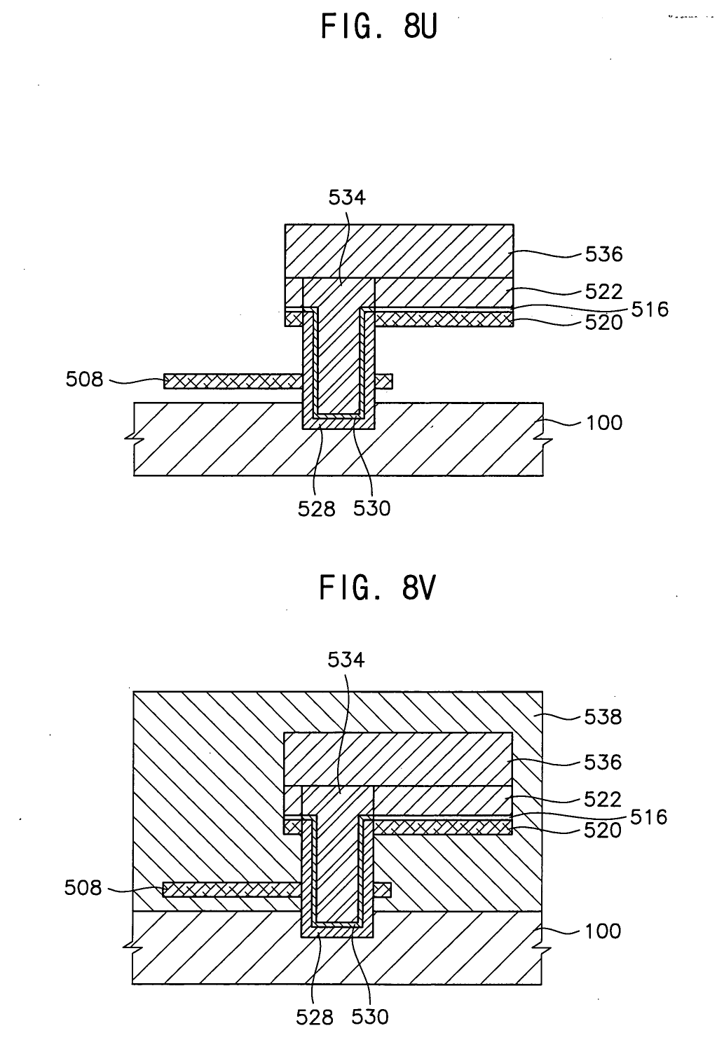

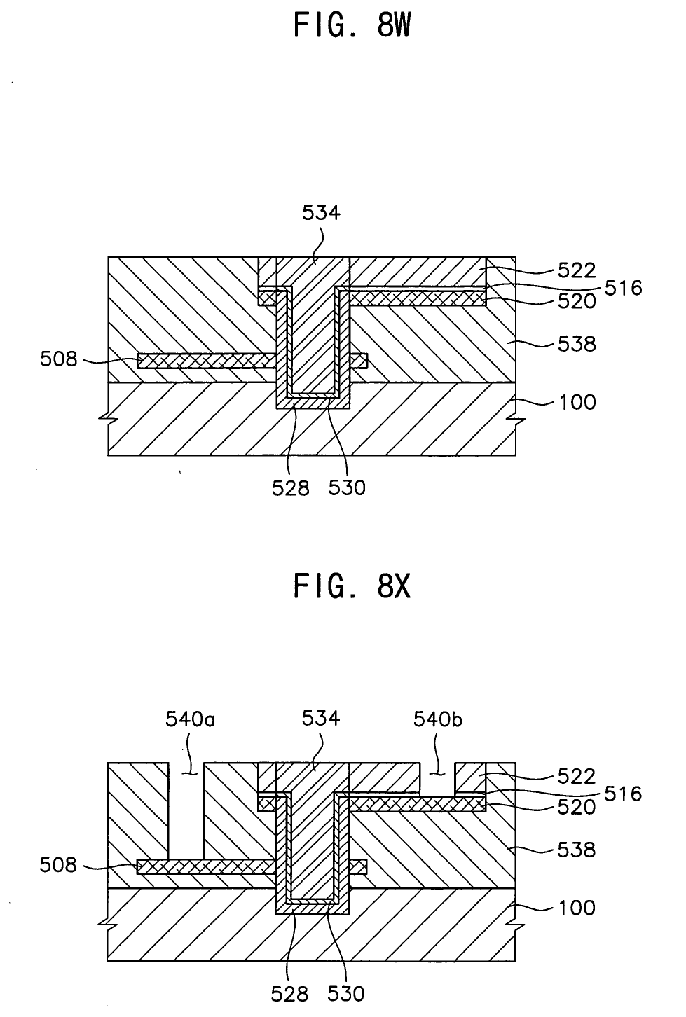

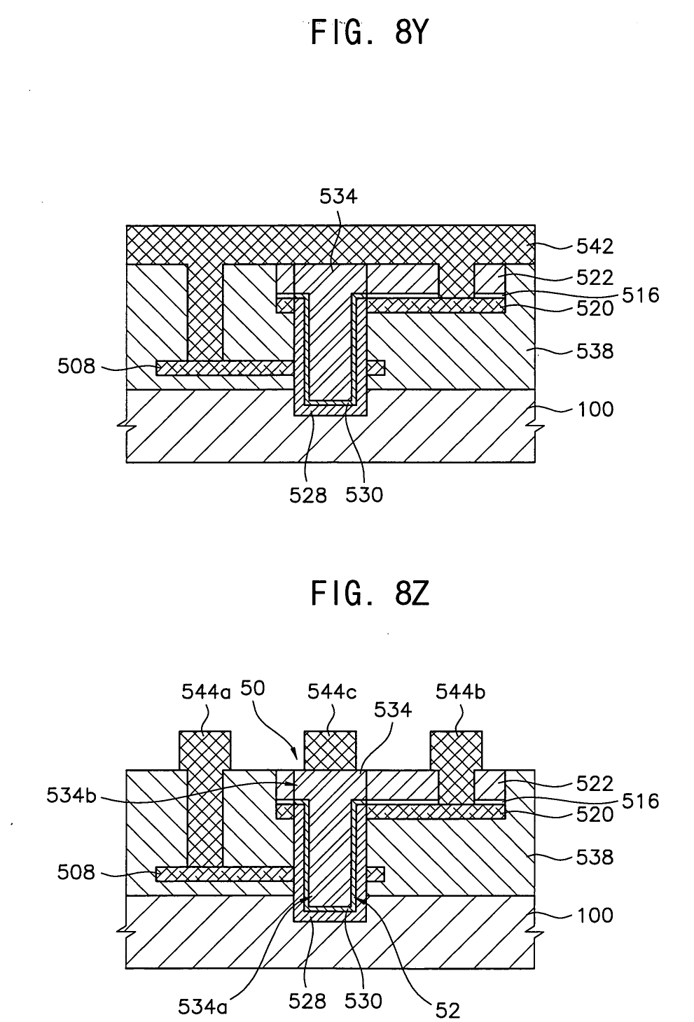

FIGS. 8A to 8Z are cross sectional views illustrating processing steps of manufacturing a semiconductor device such as a MOS transistor according to an embodiment of the present invention.

Referring to FIG. 8A, a first sacrificial layer 502 is formed on a semiconductor substrate 100. The first sacrificial layer 502 exemplarily comprises silicon germanium, and a conventional process such as an epitaxial process, a CVD process, or an UVCVD process may be utilized for forming the first sacrificial layer 502. The first sacrificial layer 502 is patterned into the photoresist pattern by a conventional photolithography process. A conventional ashing process or a strip process may remove the photoresist pattern from the first conductive layer 506.

Referring to FIG. 8E, a second sacrificial layer 510 is formed on the first conductive layer 508 and the first sacrificial layer 502, so that the first conductive layer 508 is covered with the second sacrificial layer 510. The second sacrificial layer 510 exemplarily comprises silicon germanium, and a conventional process such as an epitaxial process, a CVD process, or an UVCVD process may be utilized for forming the second sacrificial layer 510 using a silicon source gas, a germanium source gas, and a carrier gas. A thickness of the second sacrificial layer 510 may be substantially identical to the thickness of the first sacrificial layer 502 or may be greater than that of the first sacrificial layer 502.

Referring to FIG. 8F, the second sacrificial layer 510 is planarized or removed until a top surface of the first conductive pattern 508 is exposed by exemplarily using a CMP process.

Even though not shown in FIG. 8F, a first buffer oxide layer may be further formed on the first single-crystalline silicon layer 504 in FIG. 8b. The first buffer oxide layer may be removed after carrying out a doping process on the first single-crystalline silicon layer 504, or may be removed while performing the planarization process on the second sacrificial layer 510.

Referring to FIG. 8G, a third sacrificial layer 512 is formed on the first conductive layer 508 and the second sacrificial layer 510. The third sacrificial layer 512 exemplarily comprises silicon germanium, and a conventional process such as an epitaxial process, a CVD process, or an UVCVD process may be utilized for forming the third sacrificial layer 510 using a silicon source gas, a germanium source gas, and a carrier gas. A thickness of the third sacrificial layer 512 may be varied in accordance with a channel length of a MOS transistor, and in the present embodiment, is about 1000 Å.

Referring to FIG. 8H, a second single-crystalline silicon layer 514 and a second buffer oxide layer 516 are sequentially formed on the third sacrificial layer 512 by a conventional process such as an epitaxial process, a CVD process, or an UVCVD process using a silicon source gas, for example, silane (SiH₄) gas or di-chlorosilane (SiH₂Cl₂) gas, and a carrier gas, for example, hydrogen (H₂) gas, or chlorine (Cl₂) gas. The second single-crystalline silicon layer 514 may be formed to a thickness of about 400 Å to about 600 Å. However, the thickness of the second single-crystalline silicon layer may be varied in accordance with formed to a thickness of about 400 Å to about 600 Å, and in the present embodiment, to a thickness of about 500 Å. An impurity doping area (not shown) such as an N type well or a P type well may be formed at a surface portion of the substrate 100 by using an ion implantation process or a diffusion process before the first sacrificial layer 502 is formed.

A processing gas for forming the first sacrificial layer 502 includes a silicon source gas, a germanium source gas, and a carrier gas. Examples of the silicon source gas include silane (SiH₄), disilane (Si₂H₆), trisilane (Si3H₈), mono-chlorosilane (SiH₃Cl), di-chlorosilane (SiH₂Cl₂), tri-chlorosilane (SiHCl3), etc. In addition, examples of the germanium source gas include mono germane (GeH₄), di-germane (Ge₂H₄), mono-chlorogermane (GeH₃Cl), di-chlorogermane (Ge₂H₂Cl₂), tri-chlorogermane (Ge3HCl3), etc. The carrier gas may be chlorine (Cl₂) gas, hydrogen (H₂) gas or hydrochloride (HCl) gas.

Referring to FIG. 8B, a first single-crystalline silicon layer 504 is formed on the first sacrificial layer 502 by a conventional process such as an epitaxial process, a CVD process, or an UVCVD process using a silicon source gas, for example, silane (SiH₄) gas or di-chlorosilane (SiH₂Cl₂) gas; and a carrier gas, for example, hydrogen (H₂) gas or chlorine (Cl₂) gas. The first single-crystalline silicon layer 504 may be formed to a thickness of about 400 Å to about 600 Å, and in the present embodiment, to a thickness of about 500 Å. However, the thickness of the first single-crystalline silicon layer may be varied in accordance with processing conditions and circumstances, and does not limit the claim scope of the present invention.

Referring to FIG. 8C, the first single-crystalline silicon layer 504 is doped with P type or N type impurities by an ion implantation process or a diffusion process, and thus the first single-crystalline silicon layer 504 is transformed into a first conductive layer 506.

Alternatively, an epitaxial process or a CVD process may form the first conductive layer 506 using processing gas, including a silicon source gas such as the silane gas (SiH₄) and a dopant source doped in-situ into the first single-crystalline silicon layer 504. Phosphine (PH₃) gas or arsine (AsH₃) gas may be utilized as an N type dopant source, and diborane (B2₂H₆) gas may be utilized as a P type dopant source.

Referring to FIG. 8D, the first conductive layer 506 is partially removed by a conventional dry etching process such as a plasma etching process and a reactive ion etching process, thereby forming a first conductive pattern 508. Though not shown in the figures, a photoresist pattern (not shown) may be used in the above dry etching process as an etching mask. A photoresist layer (not shown) is formed on the first conductive layer 506, and is characteristics of the MOS transistor, and does not limit the claim scope of the present invention.

Referring to FIG. 8I, the second single-crystalline silicon layer 514 in FIG. 8H is doped with P type or N type impurities by an ion implantation process or a diffusion process, and thus the second single-crystalline silicon layer 514 is transformed into a second conductive layer 518.

Alternatively, an epitaxial process or a CVD process may form the second conductive layer 518 using processing gas including a silicon source gas such as the silane gas (SiH₄) and a dopant source doped in-situ into the second single-crystalline silicon layer 514. Phosphine (PH₃) gas or arsine (AsH3₃) gas may be utilized as an N type dopant source, and diborane (B₂H₆) gas may be utilized as a P type dopant source.

Referring to FIG. 8J, the second buffer oxide layer 516 and the second conductive layer 518 in FIG. 8I are partially removed by a conventional dry etching process such as a plasma etching process and a reactive ion etching process, thereby forming a second conductive pattern 520. Though not shown in figures, a photoresist pattern (not shown) may be used in the above dry etching process as an etching mask. A photoresist layer (not shown) is formed on the second buffer oxide layer 516, and is patterned into the photoresist pattern by a conventional photolithography process. A conventional ashing process or a strip process may remove the photoresist pattern from the second buffer oxide layer 516 after forming the second conductive pattern 520. In the present embodiment, the second conductive pattern 520 partially overlaps with the first conductive pattern 508. A conventional etching process may remove the second buffer oxide layer 516 after the second single-crystalline silicon layer 514 in FIG. 8H is doped with impurities.

Referring to FIG. 8K, a capping layer 522 is formed on the third sacrificial layer 512 and the second buffer oxide layer 516, so that the second conductive pattern 520 and the second buffer oxide layer 516 on the second conductive pattern 520 are covered with the capping layer 522. The capping layer 522 exemplarily comprises silicon nitride, and an LPCVD or a PECVD process may be utilized for forming the capping layer 522 using silane (SiH₄) gas, di-chlorosilane (SiH₂Cl₂) gas, and ammonia (NH₃) gas.

Referring to FIG. 8L, the capping layer 522 is planarized by using a CMP process or an etching back process.

Referring to FIG. 8M, the planarized capping layer 522 and the second buffer oxide layer 516 are partially removed to form a second opening 524 through which the second conductive pattern 520 is exposed. A photoresist pattern (not shown) is formed on the capping layer 522 by using a conventional photolithography process, and the planarized capping layer 522 and the second buffer oxide layer 516 are partially etched away by using a conventional anisotropic etching process such as a plasma etching process using the photoresist pattern as an etching mask. As an exemplary embodiment, a portion of the second conductive pattern 520 overlapped with the first conductive pattern 508 is also exposed through the second opening 524. The photoresist pattern is also removed by using the ashing process or the strip process.

Referring to FIG. 8N, a first opening 526 is formed under the second opening 524 through which a surface of the substrate 100 is exposed. The second conductive pattern 520, the third sacrificial layer 512, the first conductive pattern 508 and the first sacrificial layer 502 are sequentially removed by a conventional anisotropic etching process using the capping layer 522 including the second opening 524 as an etching mask. Here, the etching process for forming the first opening 526 is controlled so that the surface of the substrate 100 is over-etched during the above etching process, and a bottom surface of the first opening 526 is formed to be lower than the surface of the substrate 100. That is, the substrate 100 includes a recessed portion 526b on a top surface thereof, and the first opening 526 includes the recessed portion 526b of the substrate 100. Therefore, a bottom surface of the recessed portion 526b corresponds to the bottom surface 526a of the first opening 526.

Referring to FIG. 80, a channel pattern 528, which exemplarily comprises single-crystalline silicon, is formed on inner side and bottom surfaces of the first opening 526. A conventional process such as an epitaxial process, a CVD process, or an UVCVD process may be utilized for forming the channel pattern 526 using silicon source gas, for example, silane (SiH₄) gas and di-chlorosilane (SiH₂Cl₂) gas, and a carrier gas, for example, hydrogen (H₂) gas or chlorine (Cl₂) gas. In particular, the channel pattern 528 is formed at a surface portion of the substrate 100 and on side surfaces of the first sacrificial layer 502, the first conductive pattern 508, the third sacrificial layer 512 and the second conductive pattern 520, all of which define a boundary of the first opening 526. The channel pattern 526 may be formed to a thickness of about 100 Å to about 300 Å, and in the present embodiment, to a thickness of about 150 Å to about 200Å. However, the thickness of the channel pattern may be varied in accordance with characteristics of the MOS transistor, and does not limit the claim scope of the present invention.

A processing gas for forming the channel pattern 528 may include an N type or a P type dopant source with which impurities are in-situ doped into the channel pattern 528.

Referring to FIG. 8P, a gate insulation layer 530 is formed on a surface of the channel pattern 528. The gate insulation layer 530 may exemplarily comprise a silicon oxide layer or a silicon oxynitride layer, and be formed to a thickness of about 10 Å to about 70 Å by a rapid thermal process (RTP) using an oxygen (O₂) gas, a nitrogen monoxide (NO) gas, or a nitrous oxide (N₂O) gas.

Referring to FIG. 8Q, a third conductive layer 532 is formed on the capping layer 522 to a sufficient thickness to cover the first opening 526, of which an inner space is enclosed by the gate insulation layer 530, and to cover the second opening 524. The third conductive layer 532 may be doped with polysilicon. In particular, an LPCVD process may be utilized for forming the third conductive layer 532, and impurities are in-situ doped into the third conductive layer 532 during the LPCVD process.

Alternatively, a polysilicon layer is formed on the capping layer 522 to a sufficient thickness to fill up the inner space of the first opening 526 and the second opening 524 by an exemplarily LPCVD process, and then the polysilicon layer is doped with impurities by a conventional ion implantation process or an impurity diffusion process. Accordingly, the polysilicon layer is transformed into the third conductive layer 532. The third conductive layer 532 may comprise metal such as tungsten, titanium, tantalum, cobalt, molybdenum, nickel, and ruthenium, and may be formed by an MOCVD, PVD, or ALD process using a metal precursor.

A material of the third conductive layer 532 is determined in accordance with a work function of a MOS transistor to be manufactured. That is, since a threshold voltage Vth of the MOS transistor is generally varied according to the work function of the gate electrode, the material of the third conductive layer 532 needs to be determined in accordance with operation characteristics of the MOS transistor.

When the gate electrode comprises polysilicon doped with impurities, the work function of the gate electrode is varied according to the concentration of the impurities. Therefore, the control of the impurity concentration in the doping process enables the control on the work function of the gate electrode.

In addition, when the gate electrode comprises metal, implantation of nitrogen (N) or argon (Ar) atoms may control the work function of the gate electrode. In particular, the work function of the gate electrode increases in proportional to the concentration of the nitrogen (N) atoms.

As another embodiment, the ion implantation for controlling the work function of the gate electrode may be performed using the capping layer 522 as an ion implantation mask after a subsequent planarization process on the third conductive layer 532.

Referring to FIG. 8R, the conductive layer 532 in FIG. 8Q is planarized and removed by an etch-back process or a CMP process until a top surface of the capping layer 522 is exposed, and thus the conductive layer 532 only remains in the inner space of the first opening 526 and the second opening 524, thereby forming the gate electrode 534.

Referring to FIG. 8S, a hard mask 536 is formed on the gate electrode 534 and the capping layer 522 correspondently to the second conductive pattern 520. A hard mask layer (not shown) is formed on the gate electrode 534 and the capping layer 522, and a photoresist pattern (not shown) corresponding to the second conductive pattern 520 is formed on the hard mask layer by a conventional photolithography process. Then, the hard mask layer is anisotropically etched using the photoresist pattern as an etching mask, thereby forming the hard mask 536 corresponding to the second conductive pattern 520. The hard mask layer exemplarily comprises silicon oxide or silicon nitride, and a conventional CVD, an LPCVD, or a PECVD process may be utilized for forming the hard mask layer.

Referring to FIG. 8T, the capping layer 522 is partially removed by a conventional anisotropical etching process using the hard mask 536 as an etching mask, so that a surface of the third sacrificial layer 512 that comprises silicon germanium is partially exposed. A little over-etching of the third sacrificial layer 512 may be allowed without any problems.

Referring to FIG. 8U, the first, second, and third sacrificial layers 502, 510, 512 in FIG. 8T are removed exemplarily by a wet etching process using an etchant in which each etching selectivity of the first, second, and third sacrificial layers 502, 510, 512 with respect to the silicon germanium and the single-crystalline silicon is no less than about 50:1. The gate electrode 534 is prevented from being etched during the wet etching process by the hard mask 536 and the capping layer 522.

Referring to FIG. 8V, an insulation interlayer 538 is formed on the substrate 100, so that spaces occupied by the first, the second and the third sacrificial layers 502, 510, 512 in FIG. 8T are covered with the insulation interlayer 538. The insulation interlayer 538 may comprise spin on glass (SOG) or high-density plasma (HDP) oxide, and fully covers the MOS transistor structure shown in FIG. 8U.

Referring to FIG. 8W, the insulation interlayer 538 and the hard mask 536 are planarized and removed by an etch-back process or a CMP process exemplarily until a top surface of the gate electrode 534 is exposed.

Though not shown in FIG. 8W, when the gate electrode 534 comprises doped polysilicon, a metal silicide layer may be further formed on the doped polysilicon layer, thus the gate electrode 534 layer further includes the metal silicide layer. A metal layer (not shown) is formed on the gate electrode 534 by a conventional deposition process, and the metal layer is transformed into a metal silicide layer by a conventional silicidiation process. After the silicidiation process, the remaining metal layer is removed using an etching process.

Although the above exemplary embodiments discuss the insulation interlayer formed after the first to third sacrificial layers 502, 510, 512 are removed, the insulation interlayer could also be formed after all of the first to third sacrificial layers 502, 510 and 512, the second buffer oxide layer 516, the capping layer 522 and the hard mask 536 are removed, as will be realized by one of ordinary skill in the art.

Referring to FIG. 8X, first and second contact holes 540a and 540b are formed for partially exposing the first and second conductive patterns 508 and 520, respectively. A photoresist pattern (not shown) is formed on the insulation interlayer 538 by using a conventional photolithography process, and the insulation interlayer 538 is partially removed by a conventional plasma etching process or a reactive ion etching process using the photoresist pattern as an etching mask, thereby forming the first and second contact holes 540a and 540b. The photoresist pattern is removed after the etching process for forming the first and second contact holes 540a and 540b.

Referring to FIG. 8Y, a metal layer is formed on the insulation interlayer 538, the capping layer 522 and the gate electrode 534 to a sufficient thickness to cover the first and second contact holes 540a and 540b in FIG. 8X. The metal layer 542 exemplarily comprises aluminum, copper, tungsten, tantalum, or titanium, and is formed by an MOCVD or a PVD process.

Referring to FIG. 8Z, the metal layer 542 is partially removed to thereby form first to third metal wirings 544a, 544b and 544c. A photoresist pattern (not shown) is formed on the metal layer 542 by using a conventional photolithography process, and the metal layer 542 is partially removed by a conventional anisotropic etching process using the photoresist pattern as an etching mask, thereby forming the first to third metal wirings 544a, 544b and 544c. The first metal wiring 544a is electrically connected to the first conductive pattern 508, and the second metal wiring 544b is electrically connected to the gate electrode 534. The third metal wiring 544c is electrically connected to the second conductive pattern 520. The photoresist pattern is removed after the etching process for forming the first to third metal wirings544a, 544b and 544c.

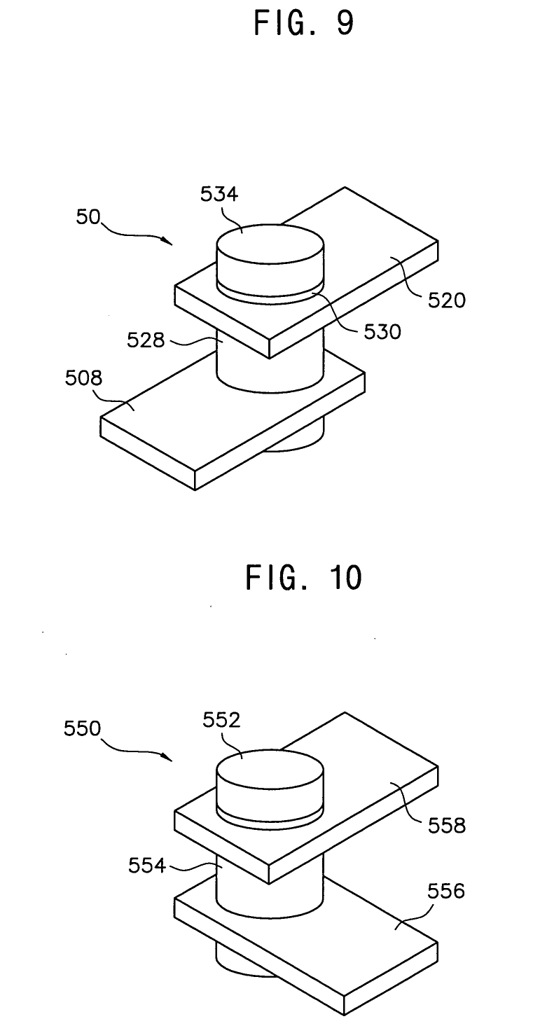

FIG. 9 is a perspective view illustrating the MOS transistor formed by the processing steps illustrated in FIGS. 8A to 8Z.

Referring to FIGS. 8Z and 9, the MOS transistor 50 includes a gate structure 52 of a pillar shape extending from a substrate in a vertical direction, a channel pattern 528 that encloses the gate structure 52 and makes contact with an outer surface of the gate structure 52, a first conductive pattern 508 extending from a lower portion of the channel pattern in a first direction perpendicular to the channel pattern and in parallel with the substrate, and a second conductive pattern extending from an upper portion of the channel pattern in a second direction perpendicular to the channel pattern and in parallel with the substrate.

The first and second conductive patterns 508 and 520 function as a source/drain in the MOS transistor 50, and cover the lower and upper portions of the channel pattern 528. As an exemplary embodiment, the first and second conductive patterns 508 and 520 extend in an opposite direction with each other from the channel pattern 528.

For example, the gate structure 52 has a pillar shape having a circular cross sectional surface, and includes a gate electrode 534 comprising a conductive material and a gate insulation layer 530 positioned on an outer surface of the gate electrode 534. The channel pattern 528 has a cylindrical shape of which the top portion is open in accordance with a profile of the gate insulation layer 530. The cylindrical channel pattern 528 of which the top portion is open has an inner diameter corresponding to an outer diameter of the gate insulation layer 530, an inner side surface that makes contact with the gate insulation layer 530 and an outer side surface that makes electrical contact with the first and second conductive patterns 508 and 520.

In detail, the gate electrode 534 includes a first pillar 534a (not shown) having a first diameter, and a second pillar 534b (not shown) that is disposed on a top surface of the first pillar 534a and has a second diameter greater than the first diameter. In the present embodiment, the first and second pillars are integrally formed into a body. The channel pattern encloses the first pillar 534a, and the outer diameter thereof is the same as the second diameter of the second pillar 534b. The gate insulation layer 530 is interposed between the first pillar 534a and the channel pattern 528.

The channel region of the MOS transistor 50 is disposed on a portion of the channel pattern 528 between the first conductive pattern 508 and the second conductive pattern 520, and has a circular tube shape or a pillar ring shape. Accordingly, a channel length of the MOS transistor 50 is determined in accordance with the distance between the first conductive pattern 508 and the second conductive pattern 520. That is, the channel length of the MOS transistor 50 is determined in accordance with a thickness of the third sacrificial layer 512 in FIG. 8G.

A channel width of the MOS transistor 50 is determined in accordance with a first diameter of the gate electrode 534. That is, the channel width of the MOS transistor 50 is determined in accordance with an inner diameter of the second opening 526 in FIG. 8N and a width of the channel pattern 528. As an exemplary embodiment, the channel pattern may have a thickness of about 100 Å to about 300 Å.

Accordingly, control of the length and width of the channel may considerably prevent the short channel effect and a narrow width effect in the MOS transistor, and thus a process failure due to the short channel effect and the narrow width effect caused by the reduction of the channel size according to a recent trend of high integration is effectively prevented.

Although the above exemplary embodiments discuss the gate electrode having a circular cross sectional surface, the gate electrode could also have any other cross sectional shape known to one of the ordinary skill in the art. Accordingly, an optimal channel width of the MOS transistor may be determined by altering the cross sectional shape of the cross sectional shape of the gate electrode.

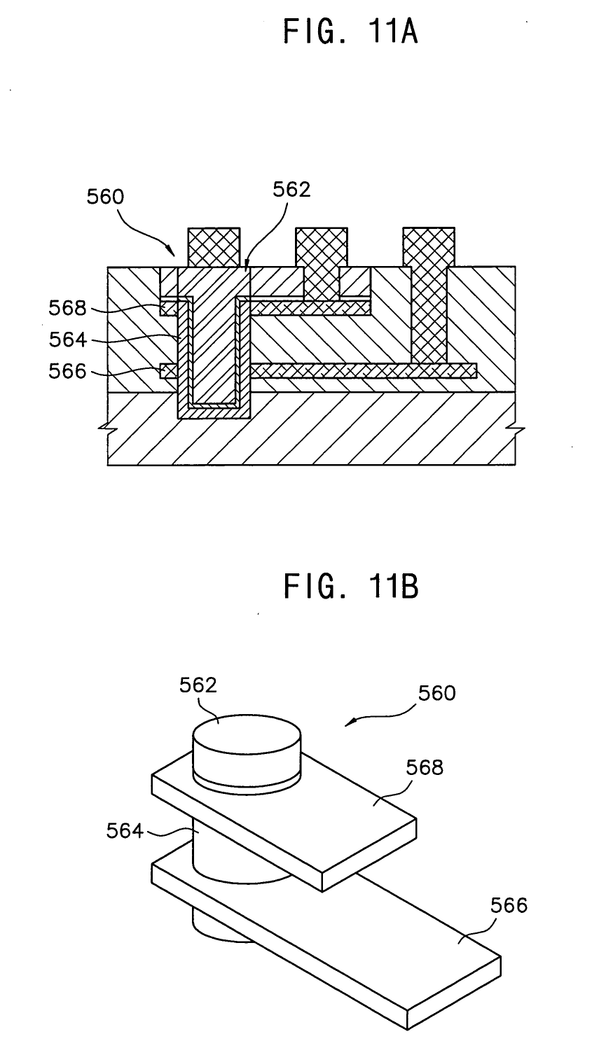

FIG. 10 is a perspective view of a first modified MOS transistor based on the MOS transistor shown in FIG. 9.

Referring to FIG. 10, the first modified MOS transistor 550 formed by another embodiment of the present invention includes a gate structure 552 of a pillar shape extending from a substrate in a vertical direction, a channel pattern 554 enclosing a side surface of the gate structure 552, and first and second conductive patterns 556 and 558 extending from lower and upper portions of the channel pattern 554.

In the present embodiment, the first conductive pattern 556 extends in a first direction perpendicular to the channel pattern and in parallel with the substrate, and the second conductive pattern 558 extends in a second direction perpendicular to the channel pattern and in parallel with the substrate. The first conductive pattern 556 exemplarily extends at an angle of about 90° with respect to the second conductive pattern 558. The angle between the first and second conductive patterns may be varied in accordance with characteristics of a MOS transistor. A layout of a semiconductor device such as a data storing system and a data processing system including the MOS transistor 550 may be improved by variation of the angle between the first and second conductive patterns 556 and 558.

FIG. 11A is a perspective view illustrating a second modified MOS transistor based on the MOS transistor shown in FIG. 9, and FIG. 11B is a cross sectional view illustrating the second modified MOS transistor shown in FIG. 11A.

Referring to FIGS. 11A and 11B, the second modified MOS transistor 560 includes a gate structure 562 of a pillar shape, a channel pattern 564 enclosing a side surface of the gate structure 562, and first and second conductive patterns 566 and 568 extending from lower and upper portions of the channel pattern 564.

In the present embodiment, the first conductive pattern 566 extends in a first direction perpendicular to the channel pattern and in parallel with the substrate, and the second conductive pattern 568 extends in a second direction perpendicular to the channel pattern and in parallel with the substrate. The first and second conductive patterns 566 and 568 exemplarily extend from the channel pattern 564 in a same direction, and the first conductive pattern 566 is exemplarily longer than the second conductive pattern 568. A layout of a semiconductor device such as a data storing system and a data processing system including the MOS transistor 560 may be improved by altering the angle between the first and second conductive patterns 566 and 568.

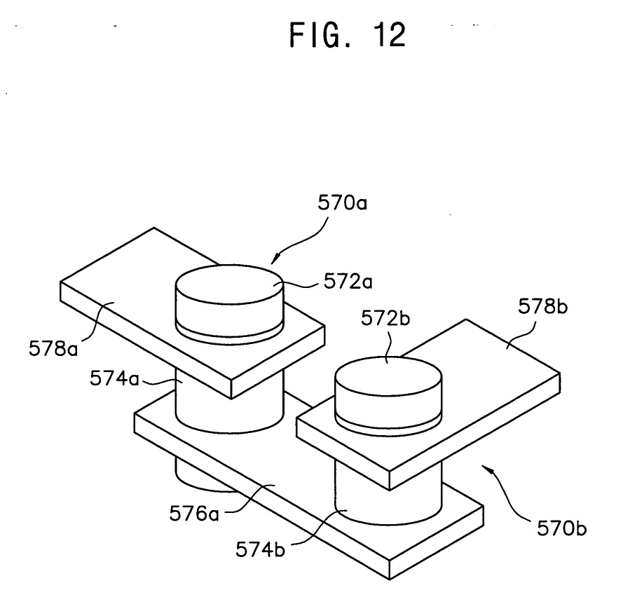

FIG. 12 is a perspective view illustrating a third modified MOS transistor based on the MOS transistor shown in FIG. 9.

Referring to FIG. 12, a pair of MOS transistors 570a and 570b holding a conductive pattern in common is arranged on a substrate. The MOS transistors 570a and 570b include gate structures 572a and 572b of a pillar shape, channel patterns 574a and 574b enclosing each of the gate structures 572a and 572b, respectively, second conductive patterns 578a and 578b enclosing upper portions of the channel patterns 574a and 574b, respectively, and extending in parallel with the substrate in a direction different from each other.

In the present embodiment, the MOS transistors 570a and 570b hold a first conductive pattern 576a in common, so that lower portions of the channel patterns 574a and 574b are interconnected with each other.

Accordingly, a plurality of the MOS transistors 570a and 570b may be connected in series due to the first conductive pattern 576a connected thereto in common. A layout of a semiconductor device such as a data storing system and a data processing system including the MOS transistors 570a and 570b interconnected with each other may be considerably improved.

Although the above exemplary embodiment discusses the first conductive pattern 576a for interconnecting the MOS transistors at lower portions of the channel patterns 574a and 574b, the MOS transistors could be interconnected by using one of the second conductive patterns 578a and 578b, as would be known to one of the ordinary skill in the art.

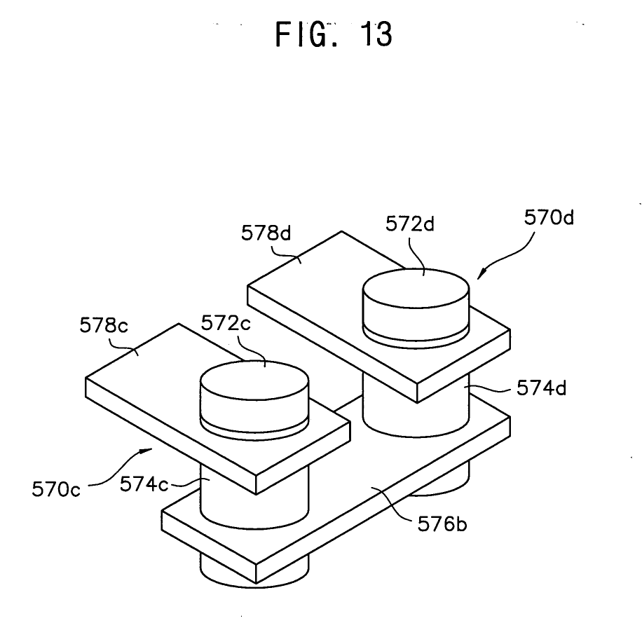

FIG. 13 is a perspective view illustrating another modified MOS transistor based on the MOS transistor shown in FIG. 9.

Referring to FIG. 13, a pair of MOS transistors 570c and 570d holding a conductive pattern in common is arranged on a substrate. The MOS transistors 570c and 570d include gate structures 572c and 572d of a pillar shape, channel patterns 574c and 574d respectively enclosing the gate structures 572c and 572d, second conductive patterns 578c and 578d respectively enclosing upper portions of the channel patterns 574c and 574d, and extending parallel with the substrate in a same direction from each other.

In the present embodiment, the MOS transistors 570c and 570d hold a first conductive pattern 576b in common, so that lower portions of the channel patterns 574c and 574d are interconnected with each other.

Accordingly, a plurality of the MOS transistors 570a and 570b may be connected in series due to the first conductive pattern 576a connected thereto in common. A layout of a semiconductor device such as a data storing system and a data processing system including the MOS transistors 570a and 570b interconnected with each other may be considerably improved.

A detailed description of the elements of the MOS transistor is the same as the MOS transistors 570a and 570b with reference to FIG. 12 and will not be further described below to avoid a redundancy of explanation.

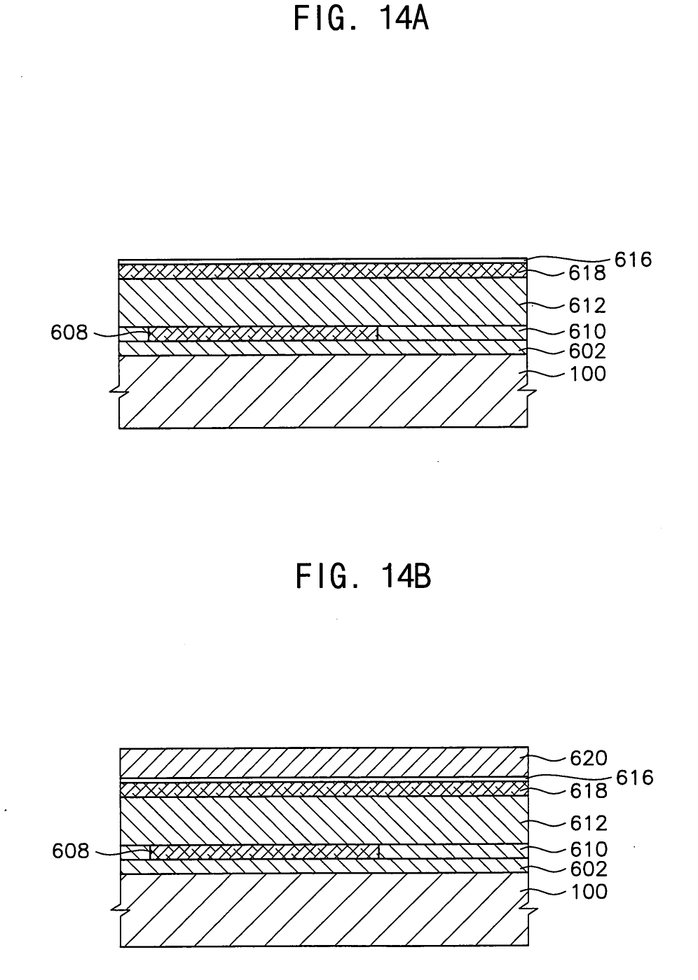

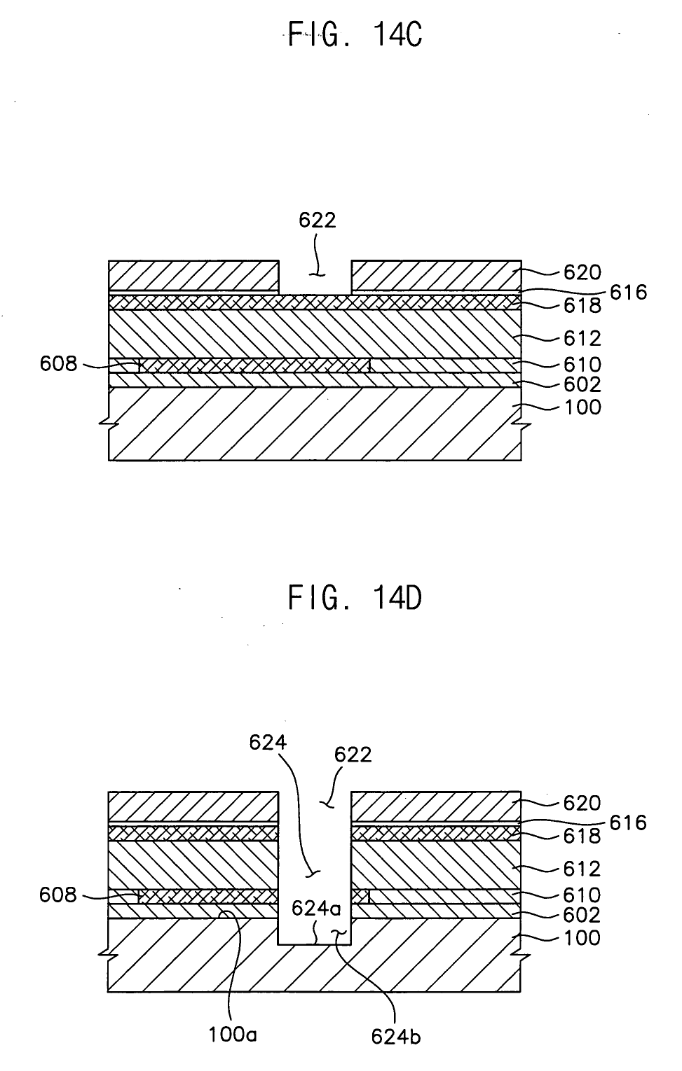

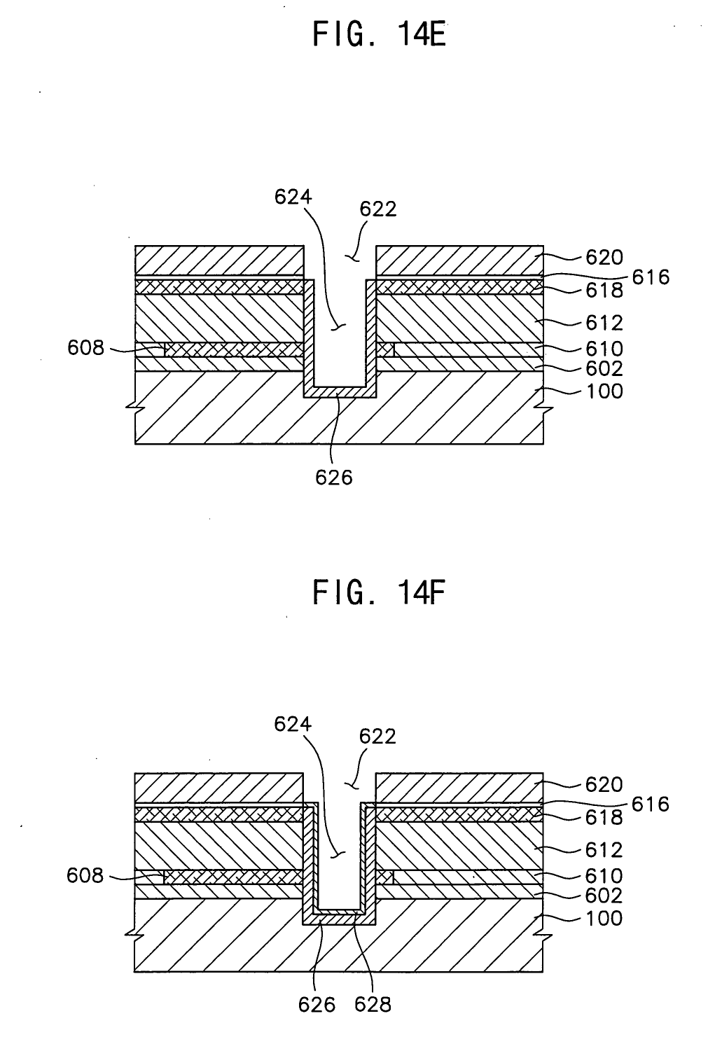

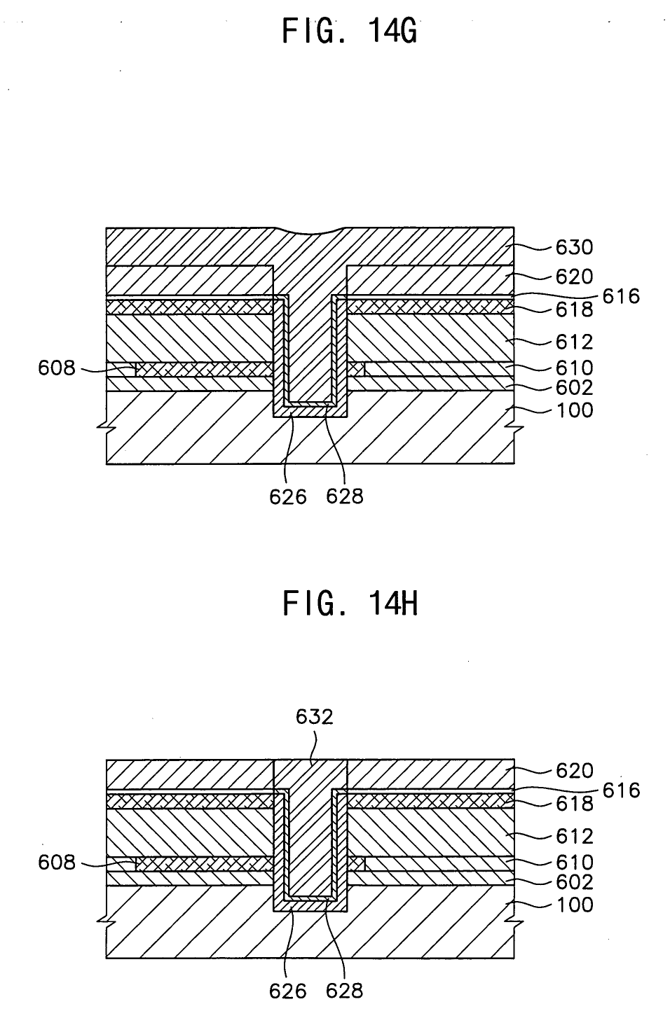

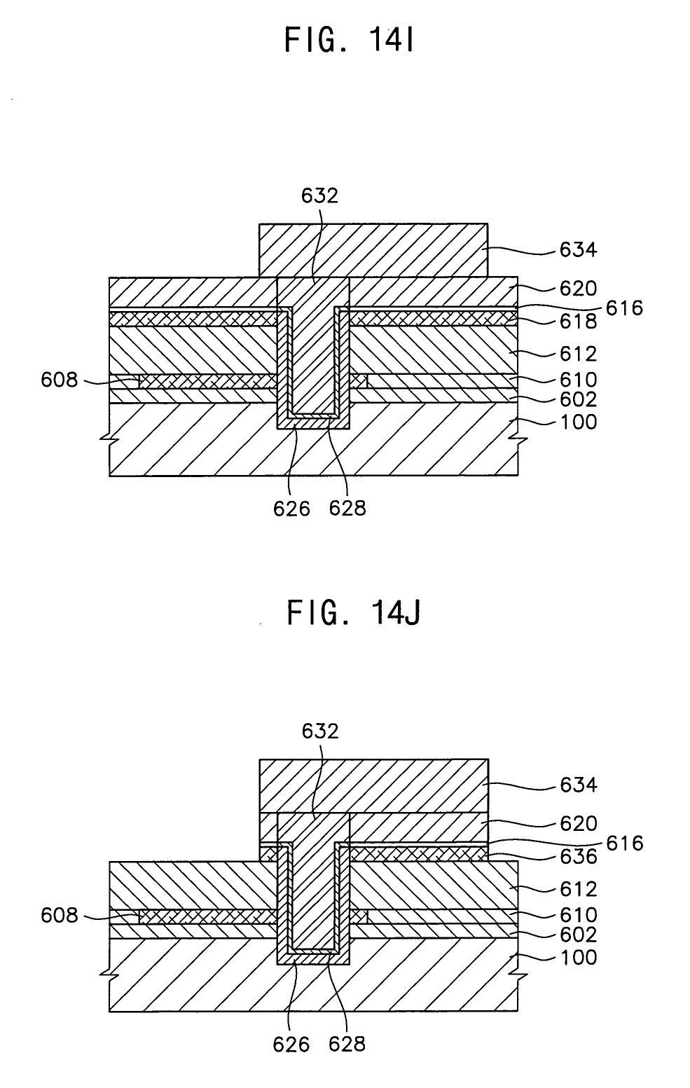

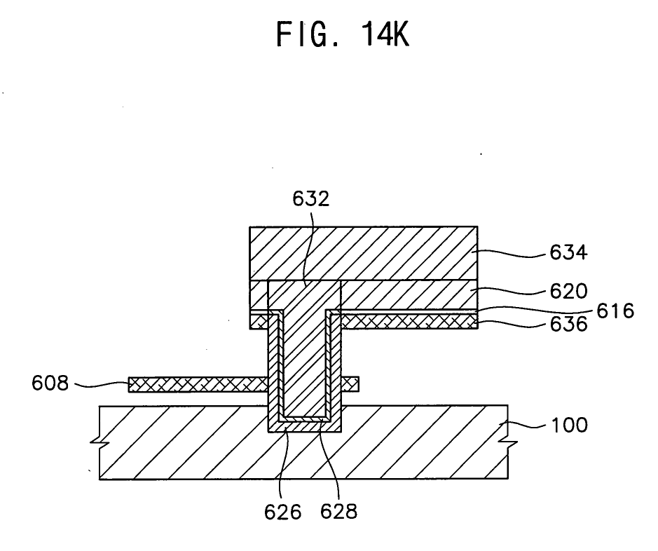

FIGS. 14A to 14K are cross sectional views illustrating processing steps of manufacturing a semiconductor device according to another embodiment of the present invention.

Referring to FIG. 14A, a first sacrificial layer 602 is formed on a semiconductor substrate 100. A first conductive pattern 608 comprising doped single-crystalline silicon and a second sacrificial layer 610 comprising silicon germanium are formed on the first sacrificial layer 602. A third sacrificial layer 612 comprising silicon germanium is formed on the first conductive pattern 608 and the second sacrificial layer 610, and a second single-crystalline silicon layer (not shown) is formed on the third sacrificial layer 612. A second buffer oxide layer 616 is formed on the second single-crystalline silicon layer, and then an impurity doping process is performed to thereby transform the second single-crystalline silicon layer into a second conductive layer 618. The above processing steps are performed in a similar way as the method of manufacturing the semiconductor device according to the first embodiment with reference to FIGS. 8A to 81, and thus a detailed description of the above processing steps will be omitted to avoid unnecessary repetitiveness.

Referring to FIG. 14B, a capping layer 620 is formed on the second buffer oxide layer 616. The capping layer 620 exemplarily comprises silicon nitride, and an LPCVD or a PECVD may be utilized for forming the capping layer 620 using di-chlorosilane gas (SiH2₂Cl₂), silane (SiH₄) gas, and ammonia (NH₃) gas.

Referring to FIG. 14C, the capping layer 620 and the second buffer oxide layer 616 are partially removed by a conventional anisotropic etching process using a photoresist pattern on the capping layer 620 as an etching mask, thereby forming a second opening 622 through which the second conductive layer 618 is exposed. The photoresist pattern is removed using an ashing process or a strip process after the etching process.

Referring to FIG. 14D, the second conductive layer 618, the third sacrificial layer 612, the first conductive pattern 608 and the first sacrificial layer 602 are sequentially and partially removed by a conventional anisotropic etching process using the capping layer including the first opening 622 as an etching mask, thereby forming a first opening 624 through which the substrate 100 is exposed. The etching process for forming the second opening 624 is prolonged so that a surface 100a of the substrate 100 is over-etched. Accordingly, a bottom surface 624a of the first opening 624 is lower than the surface 100a of the substrate 100. That is, the substrate 100 includes a recessed portion 624b on a top surface thereof, and the first opening 624 includes the recessed portion 624b of the substrate 100. Therefore, a bottom surface of the recessed portion 624b corresponds to the bottom surface 624a of the first opening 624. Referring to FIG. 14E, a channel pattern 626, which exemplarily comprises single-crystalline silicon, is formed on inner side and bottom surfaces of the first opening 624. A conventional process such as an epitaxial process, a CVD process, or an UVCVD process may be utilized for forming the channel pattern 626 using a silicon source gas, for example, silane (SiH₄) gas and di-chlorosilane (SiH₂Cl₂) gas, and a carrier gas, for example, hydrogen (H₂) gas and chlorine (Cl₂) gas. In particular, the channel pattern 626 is formed at a surface portion of the substrate 100 and on side surfaces of the first sacrificial layer 602, the first conductive pattern 608, the third sacrificial layer 612, and the second conductive layer 618, all of which define a boundary of the first opening 624.

The channel pattern 626 is formed to a thickness of about 100 Å to about 300 Å, and in the present embodiment, to a thickness of about 150 Å to about 200 Å. However, the thickness of the channel pattern 626 may be varied in accordance with characteristics of the MOS transistor, and does not limit the claim scope of the present invention.

A processing gas for forming the channel pattern 626 may include an N type or a P type dopant source with which impurities are in-situ doped into the channel pattern 626.

Referring to FIG. 14F, a gate insulation layer 628 is formed on a surface of the channel pattern 626. The gate insulation layer 628 may exemplarily comprise a silicon oxide layer or a silicon oxynitride layer, and be formed to a thickness of about 10 Å to about 70 Å by a rapid thermal process (RTP) using oxygen (O2₂) gas, nitrogen monoxide (NO) gas, or nitrous oxide (N₂O) gas.

Referring to FIG. 14G, a third conductive layer 630 is formed on the capping layer 620 to a sufficient thickness to cover the first opening 624, of which an inner space is enclosed by the gate insulation layer 628, and to cover the second opening 622. The third conductive layer 630 may be doped with polysilicon. In particular, an LPCVD process may be utilized for forming the third conductive layer 630, and impurities are in-situ doped into the third conductive layer 630 during the LPCVD process.

Alternatively, a polysilicon layer is formed on the capping layer 620 to a sufficient thickness to cover the inner space of the first opening 624 and the second opening 622 by an exemplarily LPCVD process, and then the polysilicon layer is doped with impurities by a conventional ion implantation process or an impurity diffusion process. Accordingly, the polysilicon layer is transformed into the third conductive layer 630. The third conductive layer 630 may comprise metal such as tungsten, titanium, tantalum, cobalt, molybdenum, nickel, and ruthenium, and may be formed by an MOCVD, a PVD, or a ALD process using a metal precursor.

Material of the third conductive layer 630 is determined in accordance with a work function of a MOS transistor to be manufactured. That is, since a threshold voltage Vth of the MOS transistor is generally varied according to the work function of the gate electrode, the material of the third conductive layer 630 needs to be determined in accordance with operation characteristics of the MOS transistor.

When the gate electrode comprises polysilicon doped with impurities, the work function of the gate electrode is varied according to the concentration of the impurities. Therefore, the control of the impurity concentration in the doping process enables the control on the work function of the gate electrode. In addition, when the gate electrode comprises metal, implantation of nitrogen (N) or argon (Ar) atoms may control the work function of the gate electrode. In particular, the work function of the gate electrode increases in proportional to the concentration of the nitrogen (N) atoms. As another embodiment, the ion implantation for controlling the work function of the gate electrode may be performed using the capping layer 620 as an ion implantation mask after a subsequent planarization process on the third conductive layer 630.

Referring to FIG. 14H, the third conductive layer 630 in FIG. 14G is planarized and removed by an etch-back process or a CMP process until a top surface of the capping layer 620 is exposed, and thus the third conductive layer 630 only remains in the inner space of the first opening 624 and the second opening 622, thereby forming the gate electrode 632.

Referring to FIG. 14I, a hard mask 634 is formed on the gate electrode 632 and the capping layer 620. A hard mask layer (not shown) is formed on the gate electrode 632 and the capping layer 620, and a photoresist pattern (not shown) corresponding to a second conductive pattern is formed on the hard mask layer by a conventional photolithography process. Then, the hard mask layer is anisotropically etched away using the photoresist pattern as an etching mask, thereby forming the hard mask 634. The hard mask layer exemplarily comprises silicon oxide or silicon nitride and a conventional CVD, an LPCVD, or a PECVD process may be utilized for forming the hard mask layer. The hard mask 634 is exemplarily overlapped with a portion of the first conductive pattern 608.

Referring to FIG. 14J, the capping layer 620, the second buffer oxide layer 616, and the second conductive layer 618 in FIG. 14I are partially removed by a conventional anisotropical etching process using the hard mask 634 as an etching mask until a surface of the third sacrificial layer 612 that comprises silicon germanium is partially exposed, thereby forming a second conductive pattern 636. A little over-etching of the third sacrificial layer 612 may be allowed without any problems, as can be realized by one of the ordinary skill in the art.

Referring to FIG. 14K, the first, second, and third sacrificial layers 602, 610, 612 in FIG. 14J are removed by a wet etching process using an etchant in which each etching selectivity of the first, second, and third sacrificial layers 602, 610, 612 with respect to the silicon germanium and the single-crystalline silicon is no less than about 50:1. The gate electrode 632 is prevented from being etched during the wet etching process by the hard mask 634 and the capping layer 620.

Then, an insulation interlayer (not shown) is formed on the substrate 100, so that a space occupied by the first to third sacrificial layers 602, 610 and 612 is again covered with the insulation interlayer. A plurality of metal wirings (not shown) electrically connected to the first conductive pattern 608, the gate electrode 632, and the second conductive pattern 636, respectively, is formed on the insulation interlayer. The insulation interlayer and the metal wirings are formed by a similar method as the manufacturing of the semiconductor device according to an earlier embodiment with reference to FIGS. 8V to 8Z, and thus a detail description on the above processing steps will be omitted to avoid a redundancy of explanation.

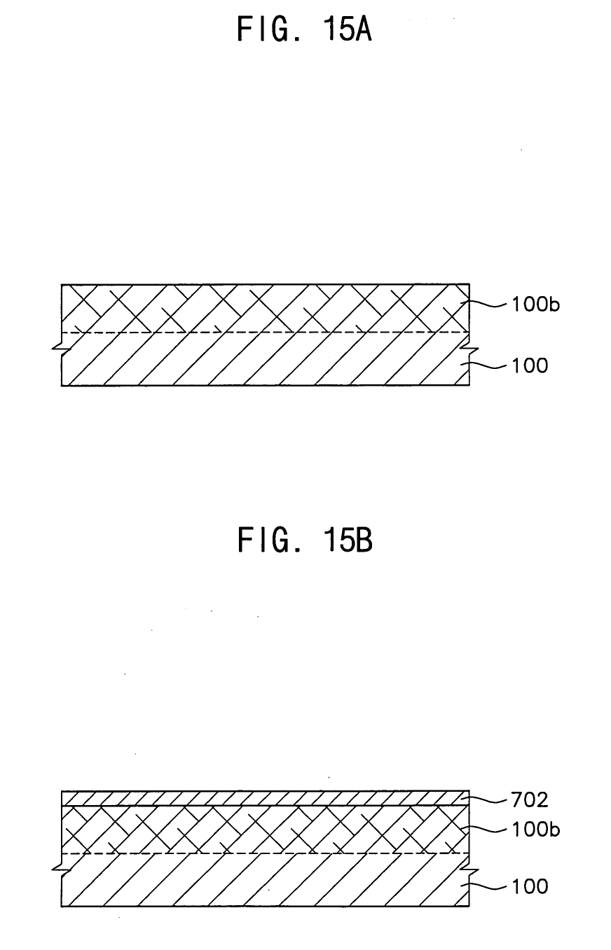

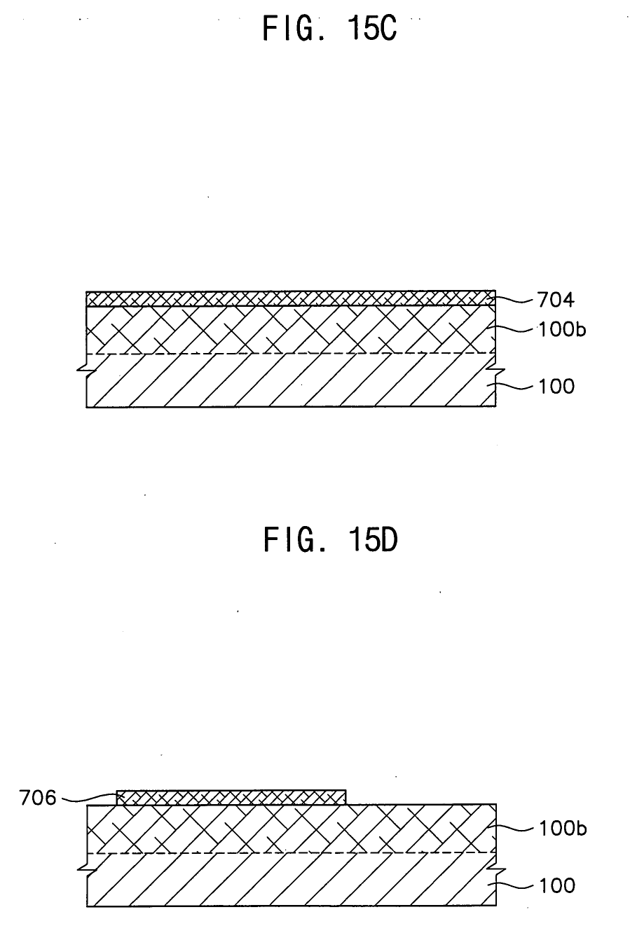

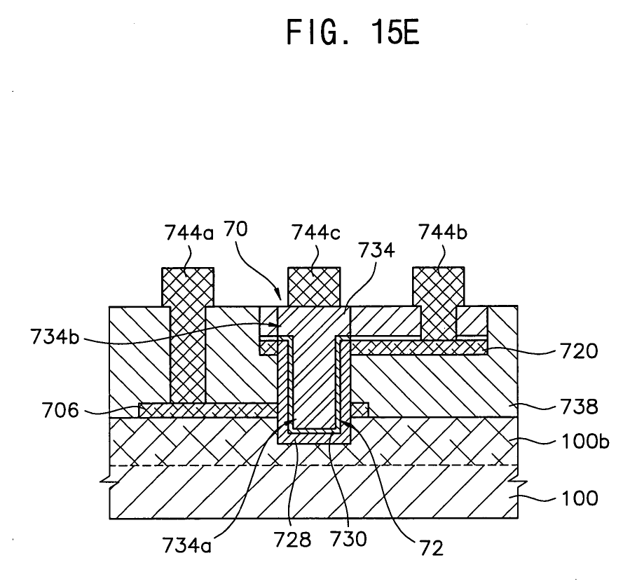

FIGS. 15A to 15E are cross sectional views illustrating processing steps of manufacturing a semiconductor device according to still another embodiment of the present invention.

Referring to FIG. 15A, an impurity doping area 100b such as an N type well or a P type well is formed at surface portions of the substrate 100 by using an ion implantation process or a diffusion process after a buffer oxide layer (not shown) is formed.

Referring to FIG. 15B, a first single-crystalline silicon layer 702 is formed on the substrate 100. A conventional process such as an epitaxial process, a CVD process, or an UVCVD process may be utilized for forming the first single-crystalline silicon layer 702 using a silicon source gas, for example, silane (SiH₄) gas and di-chlorosilane (SiH₂Cl₂) gas, and a carrier gas, for example, hydrogen (H₂) gas or chlorine (Cl₂) gas. The first single-crystalline silicon layer 702 is formed to a thickness of about 400 l Å to about 600 Å, and in the present embodiment, to a thickness of about 500 Å. However, the thickness of the first single-crystalline silicon layer 702 may be varied in accordance with characteristics of the MOS transistor, and does not limit the claim scope of the present invention. The buffer oxide layer is preferably removed from the substrate 100 before the first single-crystalline silicon layer 702 is formed.

Referring to FIG. 15C, P type or N type impurities are doped into the first single-crystalline layer 702 in FIG. 15B using an ion implantation process or a diffusion process, so that the first single-crystalline layer 702 is transformed into a first conductive layer 704.

Alternatively, an epitaxial process or a CVD process may form the first conductive layer 704 using processing gas including silicon source gas such as the silane gas (SiH₄) and a dopant source doped in-situ into the first single-crystalline silicon layer 702. Phosphine (PH₃) gas or arsine (AsH₃) gas may be utilized as an N type dopant source, and diborane (B₂H₆) gas may be utilized as a P type dopant source.

Referring to FIG. 15D, the first conductive layer 704 in FIG. 15C is partially removed by a conventional dry etching process using a photoresist pattern (not shown) as an etching mask, thereby forming a first conductive pattern 706. The photoresist pattern is formed on the first conductive layer by a conventional photolithography process, and removed by an ashing process or a strip process after the etching process is completed.

Then, various processing steps are performed in a similar way as described in an earlier embodiment with reference to FIGS. 8E to 8Z or in another embodiment with reference to FIGS. 14A to 14K; and a semiconductor device 70 such as a MOS transistor is formed on the substrate 100 as shown in FIG. 15E. A detailed description of the processing steps for manufacturing the semiconductor device 70 will be omitted to avoid a redundancy of explanation.

The semiconductor device 70 formed by the present embodiment of the invention includes a gate structure 72 extending from a substrate in a vertical direction, a channel pattern 728 that encloses the gate structure 72 and makes contact with an outer surface of the gate structure 72, a first conductive pattern 706 extending from a lower portion of the channel pattern 728 in a first direction perpendicular to the channel pattern 728 and in parallel with the substrate, and a second conductive pattern 720 extending from an upper portion of the channel pattern 728 in a second direction perpendicular to the channel pattern 728 and in parallel with the substrate.

In addition, the insulation interlayer 738 encloses the channel pattern 728 and the first and second conductive patterns 706 and 720, and a plurality of metal wirings 744a, 744b and 744c is electrically connected to the gate electrode 734, a first conductive pattern 706, and a second conductive pattern 720, respectively.

The gate structure 72 includes a gate electrode 734 and a gate insulation layer 730. The gate electrode 734 includes a first pillar 734a having a first diameter and a second pillar 734b that is disposed on a top surface of the first pillar 734a and has a second diameter larger than the first diameter. In the present embodiment, the first and second pillars 734a and 734b are integrally formed into a body. The gate insulation layer 730 makes contact with side and bottom surfaces of the first pillar 734a and a bottom surface of the second pillar 734b. The channel pattern 728 has a cylindrical shape having an outer diameter identical to an inner diameter of the second pillar 734b, and is contact with the gate insulation layer 730.

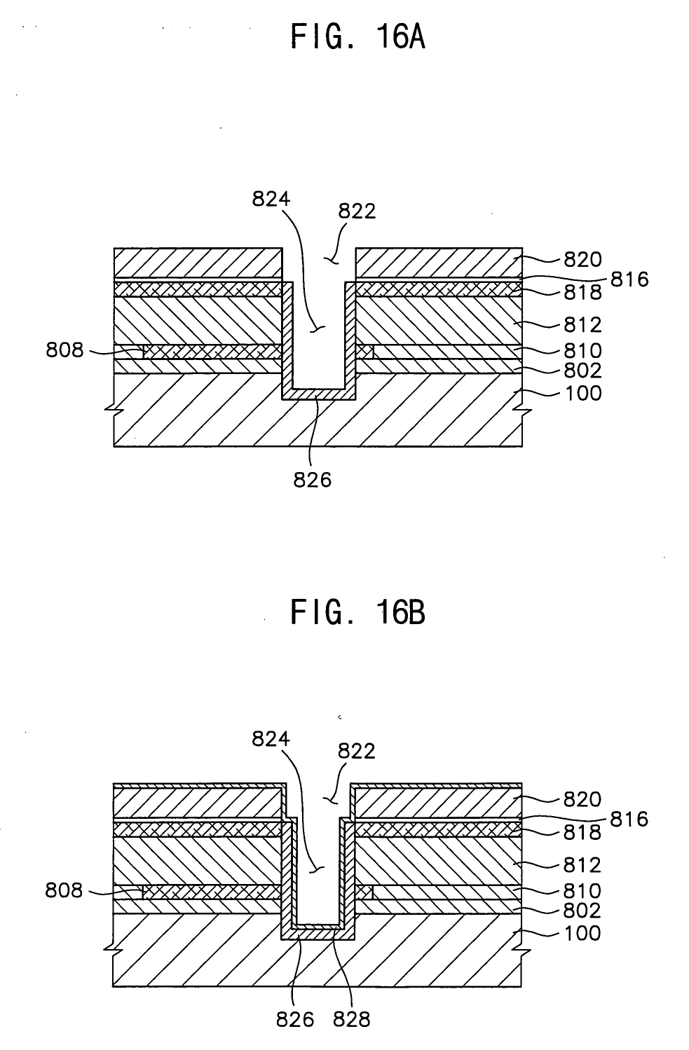

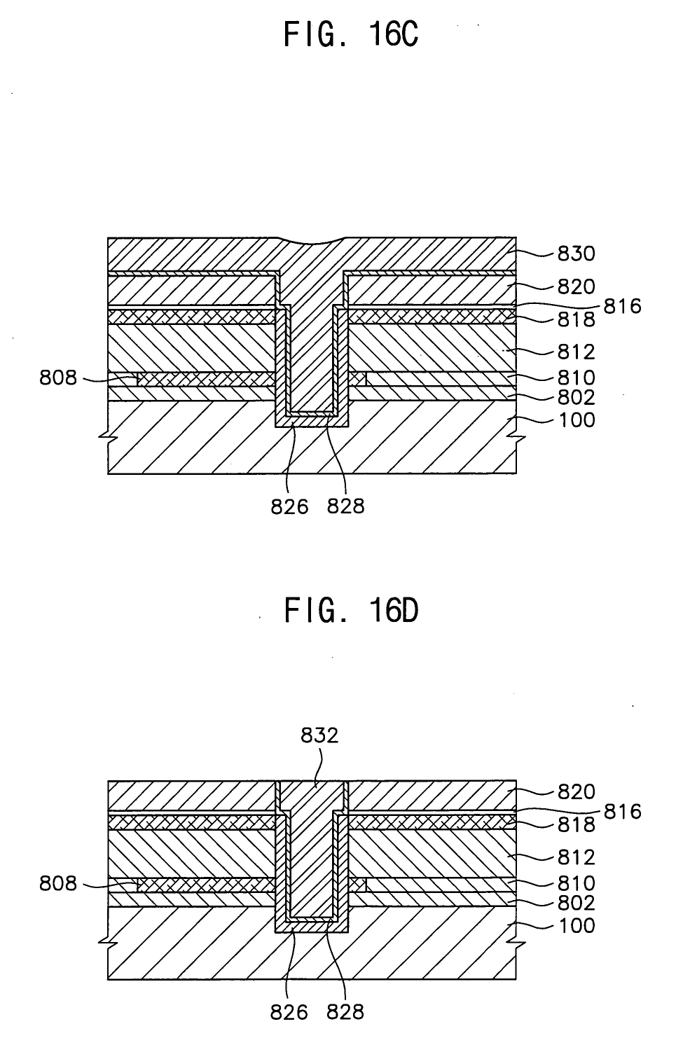

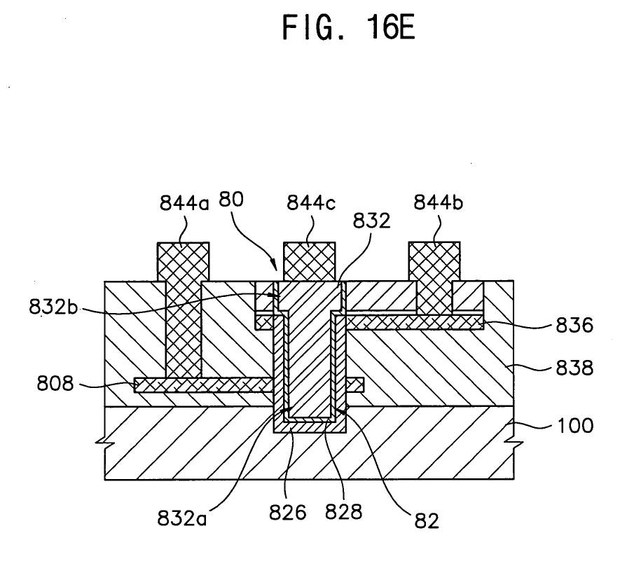

FIGS. 16A to 16E are cross sectional views illustrating processing steps of manufacturing a semiconductor device according to still another embodiment of the present invention.

Referring to FIG. 16A, a first sacrificial layer 802 that exemplarily comprises silicon germanium is formed on a substrate 100. A first conductive pattern 808 that comprises single-crystalline silicon doped with impurities and a second sacrificial layer 810 are sequentially formed on the first sacrificial layer 802. A third sacrificial layer 812 that comprises silicon germanium is formed on the first conductive pattern 808 and the second sacrificial layer 810, and a second single-crystalline silicon layer (not shown) is formed on the third sacrificial layer 812. A second buffer oxide layer 816 is formed on the second single-crystalline silicon layer, and the second single-crystalline silicon layer is doped with impurities, so that the second single-crystalline silicon layer is transformed into a second conductive layer 818. A capping layer 820 including a second opening 822 is formed on the second buffer oxide layer 816. The second buffer oxide layer 816, the second conductive layer 818, the third sacrificial layer 812, the first conductive pattern 808 and the first sacrificial layer 802 are sequentially etched away using the capping layer 820 as an etching mask, thereby forming a first opening 824 through which a surface of the substrate 100 is partially exposed. A channel pattern 826 that comprises single-crystalline silicon is formed on inner and bottom surface of the first opening 824. The above processing steps are performed in a similar way as the method of manufacturing the semiconductor device according to the earlier embodiment with reference to FIGS. 14Ato 14E, and thus a detail description on the above processing steps will be omitted to avoid a redundancy of explanation.

Referring to FIG. 16B, a gate insulation layer 828 is formed on a top surface of the capping layer 820, on inner and bottom surfaces of the second opening 822, and on the channel pattern 826 formed along a profile of the first opening 824. The gate insulation layer 828 may exemplarily be a silicon oxide layer, a silicon oxynitride layer, a metal oxide layer, or a composite layer thereof. An LPCVD process may be utilized for forming the silicon oxide layer and the silicon oxynitride layer, and an MOCVD or an ALD may be utilized for forming the metal oxide layer. Examples of the metal oxide include a tantalum oxide (Ta₂O5₅) layer, a tantalum oxynitride (TaON) layer, a titanium oxide (TiO₂) layer, an aluminum oxide (Al₂O₃) layer, a yttrium oxide (Y₂O₃) layer, a zirconium oxide (ZrO₂) layer, a hafnium oxide (HfO₂) layer, a barium titanate oxide (BaTiO₃) layer, a strontium titanate oxide (SrTiO₃) layer, etc.

Referring to FIG. 16C, a third conductive layer 830 is formed on the capping layer 820 to a sufficient thickness to cover the first opening 824, of which an inner space is enclosed by the gate insulation layer 828, and to cover the second opening 822. The third conductive layer 830 may be doped with polysilicon. In particular, an LPCVD process may be utilized for forming the third conductive layer 830, and impurities are in-situ doped into the third conductive layer 830 during the LPCVD process.

Alternatively, a polysilicon layer is formed on the capping layer 820 to a sufficient thickness to cover the inner space of the first opening 824 and the second opening 822 by an LPCVD process, and then the polysilicon layer is doped with impurities by a conventional ion implantation process or an impurity diffusion process. Accordingly, the polysilicon layer is transformed into the third conductive layer 830. The third conductive layer 830 may comprise metal such as tungsten, titanium, tantalum, cobalt, molybdenum, nickel, and ruthenium, and may be formed by an MOCVD, a PVD, or an ALD process using a metal precursor.

Referring to FIG. 16D, the third conductive layer 830 in FIG. 16C and the gate insulation layer 828 in FIG. 16C on the capping layer 820 are planarized and removed by an etch-back process or a CMP process until a top surface of the capping layer 820 is exposed, and thus the third conductive layer 830 only remains in the inner space of the second opening 824 and the first opening 822, thereby forming the gate electrode 832.

Then, various processing steps are performed in a similar way as described in the earlier embodiment with reference to FIGS. 14I to 14K, and thus a semiconductor device 80 such as a MOS transistor is formed on the substrate 100 as shown in FIG. 16E. A detail description on the processing steps for manufacturing the semiconductor device 80 will be omitted to avoid a redundancy of explanation.

The semiconductor device 80 formed by the present embodiment of the invention includes a gate structure 82 extending from a substrate 100 in a vertical direction, a channel pattern 826 that encloses the gate structure 82 and makes contact with an outer surface of the gate structure 82, a first conductive pattern 808 extending from a lower portion of the channel pattern 826 in a first direction perpendicular to the channel pattern 826 and in parallel with the substrate, and a second conductive pattern 836 extending from an upper portion of the channel pattern 826 in a second direction perpendicular to the channel pattern 826 and in parallel with the substrate.

In addition, the insulation interlayer 838 encloses the channel pattern 826 and the first and second conductive patterns 808 and 836, and a plurality of metal wirings 844a, 844b and 844c is electrically connected to the gate electrode 832, a first conductive pattern 808, and a second conductive pattern 836, respectively.

The gate structure 82 includes a gate electrode 832 and a gate insulation layer 828. The gate electrode 832 includes a first pillar 832a having a first diameter and a second pillar 832b that is disposed on a top surface of the first pillar 832a and has a second diameter greater than the first diameter. In the present embodiment, the first and second pillars 832a and 832b are integrally formed into a body. The gate insulation layer 828 makes contact with side and bottom surfaces of the first pillar 832a and a bottom surface of the second pillar 832b. The channel pattern 826 has a cylindrical shape having an outer diameter identical to an inner diameter of the second pillar 832b, and is contact with the gate insulation layer 828.

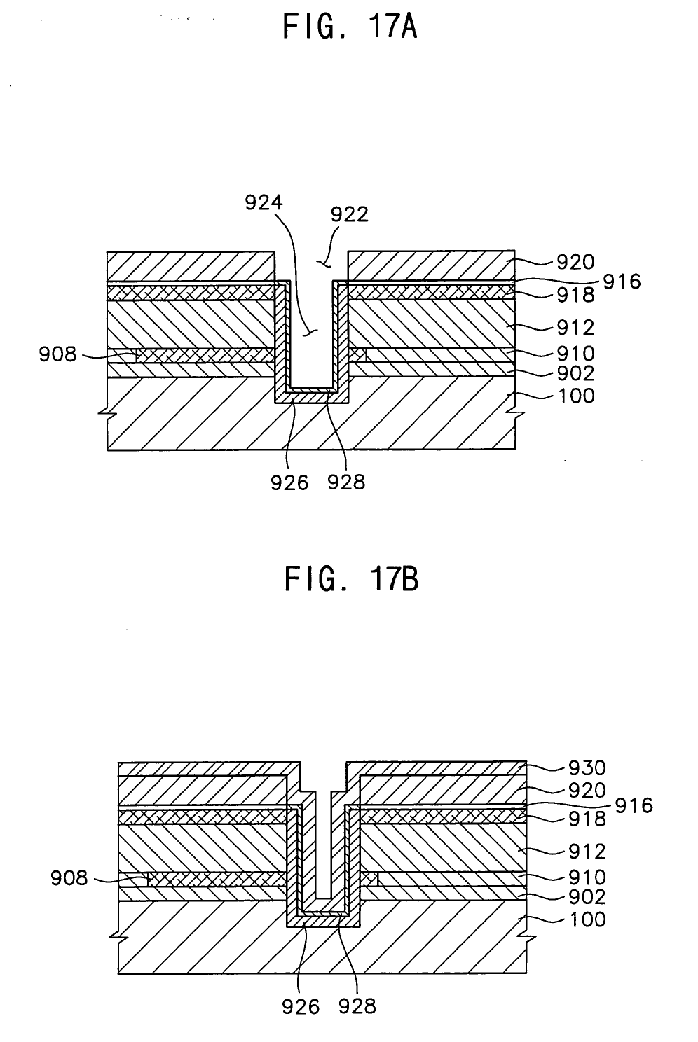

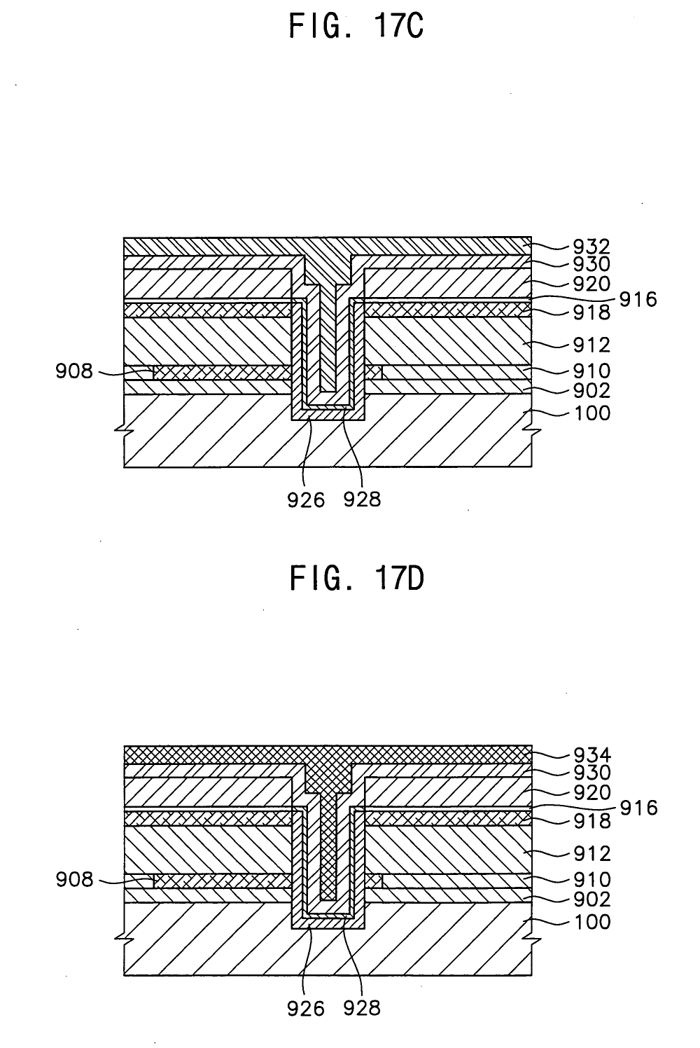

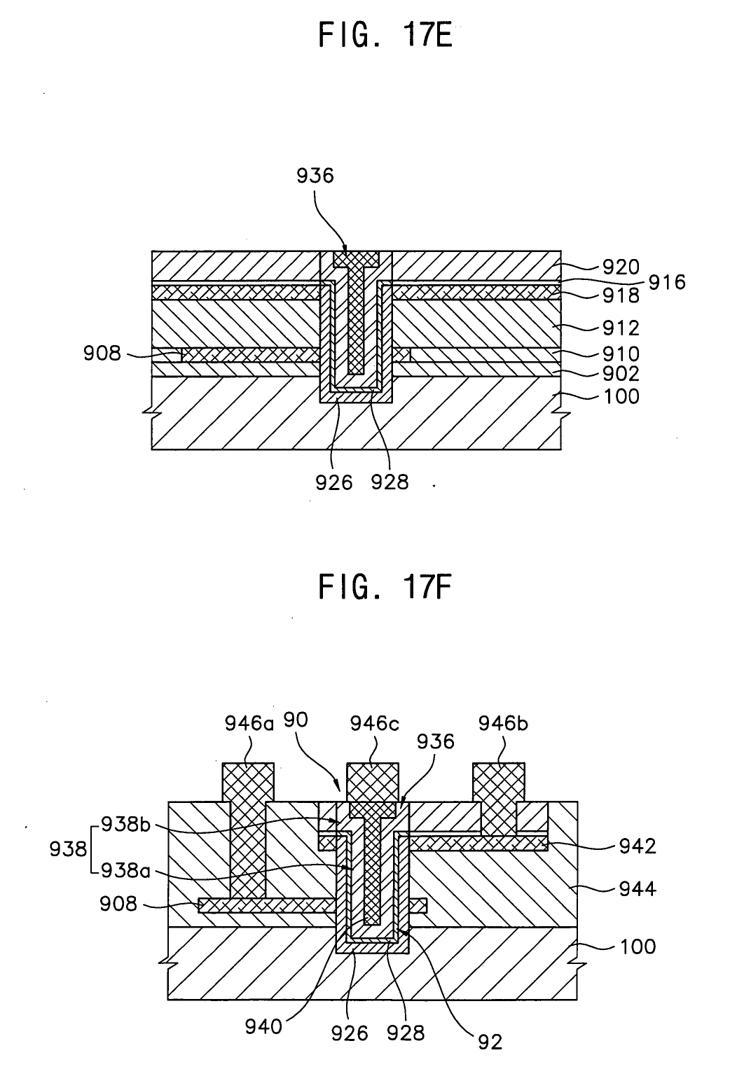

FIGS. 17A to 17E are cross sectional views illustrating processing steps of manufacturing a semiconductor device according to still another embodiment of the present invention.

Referring to FIG. 17A, a first sacrificial layer 902 that exemplarily comprises silicon germanium is formed on a substrate 100. A first conductive pattern 908 that comprises single-crystalline silicon doped with impurities and a second sacrificial layer 910 are sequentially formed on the first sacrificial layer 902. A third sacrificial layer 912 that comprises silicon germanium is formed on the first conductive pattern 908 and the second sacrificial layer 910, and a second single-crystalline silicon layer (not shown) is formed on the third sacrificial layer 912. A second buffer oxide layer 916 is formed on the second single-crystalline silicon layer, and the second single-crystalline silicon layer is doped with impurities, so that the second single-crystalline silicon layer is transformed into a second conductive layer 918. A capping layer 920 including a second opening 922 is formed on the second buffer oxide layer 916. The second buffer oxide layer 916, the second conductive layer 918, the third sacrificial layer 912, the first conductive pattern 908, and the first sacrificial layer 902 are sequentially etched away using the capping layer 920 as an etching mask, thereby forming a first opening 924 through which a surface of the substrate 100 is partially exposed. A channel pattern 926 that comprises single-crystalline silicon is formed on inner and bottom surfaces of the first opening 924, and a gate insulation layer 928 is formed on the channel pattern 926. The above processing steps are performed in a similar way as the method of manufacturing the semiconductor device according to the earlier embodiment with reference to FIGS. 14A to 14F, and thus a detail description on the above processing steps will be omitted to avoid unnecessary repetitiveness.

Referring to FIG. 17B, a third conductive layer 930 is uniformly formed on top surfaces of the capping layer 920 and the second buffer oxide layer 916 and inner surfaces of the first opening 924 of which an inner space is enclosed by the gate insulation layer 928. The third conductive layer 930 may comprise doped polysilicon. In particular, an LPCVD process may be utilized for forming the third conductive layer 930, and impurities are in-situ doped into the third conductive layer 930 during the LPCVD process.

Referring to FIG. 17C, a metal layer 932 is formed on the third conductive layer 930 to a sufficient thickness to cover inner spaces of the first and second openings 924 and 922 in FIG. 17A. The metal layer 932 may comprise metal such as tungsten, titanium, tantalum, cobalt, nickel, and ruthenium, and may be formed by an MOCVD or an ALD process using a metal precursor.

Referring to FIG. 17D, a heat treatment is performed on the substrate 100 including the metal layer 932 in FIG. 17C, thus the metal layer 932 is reacted with the doped polysilicon. Accordingly, the metal layer 932 is transformed into a metal silicide layer 934 due to the heat treatment.

Referring to FIG. 17E, the metal silicide layer 934 and the third conductive layer 930 are planarized and removed by an etch-back process or a CMP process until a top surface of the capping layer 920 is exposed, and thus the metal silicide layer 934 only remains in the inner spaces of the first and second openings 924 and 922, limited by the third conductive layer 930, thereby forming a gate electrode 936.

Then, various processing steps are performed in a similar way as described in the earlier embodiment with reference to FIGS. 14I to 14K, and thus a semiconductor device 90 such as a MOS transistor is formed on the substrate 100 as shown in FIG. 17F. A detail description on the processing steps for manufacturing the semiconductor device 90 will be omitted to avoid a redundancy of explanation.

The semiconductor device 90 formed by the present embodiment of the invention includes a gate structure 92 extending from a substrate 100 in a vertical direction, a channel pattern 926 that encloses the gate structure 92 and makes contact with an outer surface of the gate structure 92, a first conductive pattern 908 extending from a lower portion of the channel pattern 926 in a first direction perpendicular to the channel pattern 926 and in parallel with the substrate 100, and a second conductive pattern 936 extending from an upper portion of the channel pattern 926 in a second direction perpendicular to the channel pattern 926 and in parallel with the substrate 100.

In addition, the insulation interlayer 944 encloses the channel pattern 926 and the first and second conductive patterns 908 and 942, and a plurality of metal wirings 946a, 946b, and 946c is electrically connected to the gate electrode 936, a first conductive pattern 908, and a second conductive pattern 942, respectively.

The gate structure 92 includes the gate electrode 936 and a gate insulation layer 928. The gate electrode 936 includes a third conductive pattern 938 and a metal silicide plug 938 filling inside the third conductive pattern 938. The third conductive pattern 938 includes a first cylinder 938a having a first outer diameter and a second cylinder 938b having a second outer diameter greater than the first outer diameter of the first cylinder 938a. The gate insulation layer 928 makes contact with side and bottom surfaces of the first cylinder 938a and a bottom surface of the second cylinder 938b. Alternatively, the gate insulation layer 928 may make contact with all outer surface of the gate electrode 936 except an upper surface thereof.

According to the present invention, the channel pattern has a cylindrical shape, and encloses the side surface of the gate structure extending from the semiconductor substrate in a vertical direction. The first conductive pattern extending from a lower portion of the channel pattern and the second conductive pattern extending from an upper portion of the channel pattern function as a source/drain of a MOS transistor, respectively.

A channel length of the MOS transistor is determined in accordance with a distance between the first and second conductive patterns, and a channel width of the MOS transistor is determined by a diameter of the gate structure. Accordingly, a short channel effect and a narrow width effect are sufficiently prevented in a MOS transistor.

In particular, since a length and a width of the channel in the MOS transistor of the present invention are easily controlled, a punch through and a carrier mobility due to the short channel effect are remarkably improved, and the threshold voltage due to the narrow width effect is considerably reduced. Accordingly, the performance of the MOS transistor may be improved due to an effective prevention of the short channel effect and the narrow width effect.

In addition, the first and second conductive patterns extend at various angles, thus the applications including the MOS transistor of the present invention such as a data storing device and a data processing device may have various modifications in a layout thereof.

Embodiments of the invention may be practiced in many ways. What follows are exemplary, non-limiting descriptions of some4 embodiments of the invention.

Although the exemplary embodiments of the present invention have been described, it is understood that the present invention should not be limited to these exemplary embodiments but various changes and modifications can be made by one skilled in the art within the spirit and scope of the present invention as hereinafter claimed.

According to an embodiment of the present invention, there is provided a gate structure that comprises a gate electrode formed on a substrate and including conductive material, and a gate insulation layer enclosing a side surface of the gate electrode.

According to another embodiment of the present invention, there is provided a semiconductor device including the above-described gate structure. The semiconductor device includes a gate structure, a channel pattern and first and second conductive patterns. The gate structure includes a gate electrode formed on a substrate and having conductive material, and a gate insulation layer enclosing a side surface of the gate electrode. The channel pattern covers a surface of the gate insulation layer. The first conductive pattern extends from a lower portion of the channel pattern, and the second conductive pattern extends from an upper portion of the channel pattern.

According to another embodiment of the present invention, there is also provided another semiconductor device including the above-described gate structure. The semiconductor device also includes a gate structure, a channel pattern and first and second conductive patterns. The gate structure includes a gate electrode having a pillar shape extending from a substrate in a vertical direction, and a gate insulation layer enclosing a side surface of the gate electrode.

The channel pattern has a cylindrical shape including inner and outer side surfaces, and the inner side surface of the channel pattern makes contact with a surface of the gate insulation layer. The channel pattern comprises single-crystalline silicon grown by an epitaxial process. The first conductive pattern doped with impurities encloses the outer side surface of the channel pattern at a lower portion thereof and extends in a first direction vertical to the channel pattern. The second conductive pattern doped with impurities encloses the outer side surface of the channel pattern at an upper portion thereof and extends in a second direction vertical to the channel pattern.

The first conductive pattern and the second conductive pattern function as a source and a drain of the MOS transistor, respectively, and exemplarily comprise single-crystalline silicon doped with impurities. A channel region of the MOS transistor is formed on the channel pattern between the first and second conductive patterns. Accordingly, a channel length of the MOS transistor may be determined in accordance with a distance between the first and second conductive patterns, thus various problems due to the short channel effect are effectively prevented. In addition, a channel width of the MOS transistor may be determined by a diameter of the channel pattern, thus various problems due to the narrow width effect are also effectively prevented.

According to still another embodiment of the present invention, there is provided a method of forming the above-described gate structure. A gate insulation layer is formed on a substrate, and includes inner and outer side surfaces. A gate electrode is formed such that the inner side surface makes contact with the gate electrode.

According to still another embodiment of the present invention, there is provided a method of manufacturing a semiconductor device including the above-described gate structure. A first conductive pattern is formed on a substrate, and a second conductive pattern is spaced apart from the first conductive pattern by a predetermined distance in a vertical direction. A channel pattern including inner and outer side surfaces is formed to make contact with the first and second patterns. A gate insulation layer is formed on the inner side surface of the channel pattern, and a gate electrode is formed to make contact with the gate insulation layer.

According to further another embodiment of the present invention, there is also provided another method of manufacturing a semiconductor device including the above-described gate structure. A first conductive layer is formed on a substrate and is patterned to thereby form a first conductive pattern. A sacrificial layer is formed on the substrate and the first conductive pattern, and a second conductive layer is formed on the sacrificial layer. A channel pattern having a pillar ring shape is formed to penetrate the second conductive layer and the sacrificial layer, and to make contact with the first conductive pattern. A gate insulation layer is formed on an inner side surface of the channel pattern, and a gate electrode is formed to make contact with the gate insulation layer. The second conductive layer is patterned to make contact with the channel pattern.

According to the present invention, a length and a width of the channel in the MOS transistor are easily controlled, thus various problems such as a punch through and carrier mobility due to the short channel effect or troubles such as a reduction of the threshold voltage due to the narrow width effect may be remarkably improved. That is, effective prevention of the short channel effect and the narrow width effect improves the performance of the MOS transistor. In addition, the first and second conductive patterns extend at various angles with each other, thus the applications including the MOS transistor of the present invention such as a data storing device and a data processing device may have various modifications in a lay-out thereof.

1. A gate structure, comprising:
a gate electrode formed on a substrate, the gate electrode including a conductive material; and
a gate insulation layer enclosing a side surface of the gate electrode.

2. The gate structure of claim 1, wherein the gate electrode has a pillar shape protruded from the substrate in a vertical direction.

3. The gate structure of claim 2, wherein the gate insulation layer has a pillar ring shape, and makes contact with the side surface of the gate electrode.

4. The gate structure of claim 2, wherein the gate insulation layer has a cylindrical shape, and makes contact with the side surface and a bottom surface of the gate electrode.

5. The gate structure of claim 1, wherein the gate electrode includes a first pillar having a first diameter and a second pillar that is formed on a top surface of the first pillar and has a second diameter greater than the first diameter, and the first and second pillars are integrally formed with each other.

6. The gate structure of claim 5, wherein the gate insulation layer is formed on a side surface and a bottom surface of the first pillar and on a bottom surface of the second pillar.

7. The gate structure of claim 1, wherein the substrate includes a recessed portion on a top surface thereof, and a lower portion of the gate electrode is formed in the recessed portion.

8. The gate structure of claim 1, wherein the gate electrode comprises a polysilicon layer doped with impurities.

9. The gate structure of claim 8, wherein the gate electrode includes a metal silicide layer on a top surface of the polysilicon layer.

10. The gate structure of claim 9, wherein the metal silicide layer comprises at least one selected from the group consisting of tungsten silicide, titanium silicide, tantalum silicide, cobalt silicide, and nickel silicide.

11. The gate structure of claim 1, wherein the gate electrode includes a conductive pattern on an inner side surface of the gate electrode and a metal silicide plug filling an inside of the conductive pattern, and the conductive pattern includes doped polysilicon with impurities.

12. The gate structure of claim 1, wherein the gate electrode comprises at least one selected from the group consisting of tungsten, titanium, tantalum, cobalt, nickel, molybdenum, and ruthenium.

13. The gate structure of claim 1, wherein the gate insulation layer includes at least one selected from the group consisting of a silicon oxide (SiₓO_{y}, wherein x and y are positive numbers) layer, a silicon oxynitride (SiON) layer, a tantalum oxide (Ta₂O₅) layer, a tantalum oxynitride (TaON) layer, a titanium oxide (TiO₂) layer, an aluminum oxide (Al₂O₃) layer, a yttrium oxide (Y₂O₃) layer, a zirconium oxide (ZrO₂) layer, a hafnium oxide (HfO₂) layer, a barium titanate oxide (BaTiO₃) layer, a strontium titanate oxide (SrTiO₃)layer and combinations thereof.

14. A semiconductor device comprising:
a gate structure including a gate electrode formed on a substrate, and a gate insulation layer enclosing a side surface of the gate electrode;
a channel pattern covering a surface of the gate insulation layer;
a first conductive pattern extending from a lower portion of the channel pattern; and
a second conductive pattern extending from an upper portion of the channel pattern.

15. The semiconductor device of claim 14, wherein the gate electrode has a pillar shape protruded from the substrate in a vertical direction, and the gate insulation layer has a pillar ring shape that makes contact with the side surface of the gate electrode.

16. The semiconductor device of claim 14, wherein the channel pattern has a pillar ring shape, the gate insulation layer is formed on an inner side surface of the channel pattern, and the gate electrode has a pillar shape that makes contact with an inner side surface of the gate insulation layer.

17. The semiconductor device of claim 14, wherein the channel pattern has a cylindrical shape including inner and outer side surfaces and an open top portion, the gate electrode having a pillar shape is received in the channel pattern, and the gate insulation layer is formed between the channel pattern and the gate electrode, so that the gate insulation layer makes contact with both of the gate electrode and the channel pattern.

18. The semiconductor device of claim 14, wherein the channel pattern includes single-crystalline silicon formed by an epitaxial process.

19. The semiconductor device of claim 18, wherein the channel pattern includes impurities doped by an in-situ process during the epitaxial process.

20. The semiconductor device of claim 14, wherein the first and the second conductive patterns cover lower and upper portions of the channel pattern, respectively.

21. The semiconductor device of claim 14, wherein the first and the second conductive patterns extend in different directions from each other.

22. The semiconductor device of claim 14, wherein the first and the second conductive patterns extend in a horizontal direction from the gate structure.

23. The semiconductor device of claim 14, wherein the first and the second conductive patterns horizontally extend from the gate structure in a same direction, respectively, and the first conductive pattern is longer than the second conductive pattern.

24. The semiconductor device of claim 14, wherein the first and the second conductive patterns comprise doped single-crystalline silicon formed by an epitaxial process and an impurity doping process.

25. The semiconductor device of claim 14, wherein the substrate has a recessed portion on a top surface thereof, and a lower portion of the gate structure is formed in the recessed portion.

26. The semiconductor device of claim 14, wherein the first conductive pattern is formed on a surface of the substrate.

27. The semiconductor device of claim 14, wherein the substrate includes an impurity doped region at a surface portion thereof.

28. The semiconductor device of claim 14, wherein the first conductive pattern is spaced apart from the substrate by a predetermined distance.

29. The semiconductor device of claim 14, further comprising an insulation interlayer between the first conductive pattern and a surface of the substrate.

30. The semiconductor device of claim 14, wherein the substrate includes an impurity doped region at a surface portion thereof.

31. A semiconductor device comprising:
a gate structure including a gate electrode having a pillar shape extending from a substrate in a vertical direction, and a gate insulation layer enclosing a side surface of the gate electrode;
a channel pattern comprising single-crystalline silicon grown by an epitaxial process and having a cylindrical shape including inner and outer side surfaces, the inner side surface of the channel pattern making contact with a surface of the gate insulation layer;
a first conductive pattern enclosing the outer side surface of the channel pattern at a lower portion thereof and extending in a first direction perpendicular to the channel pattern; and
a second conductive pattern enclosing the outer side surface of the channel pattern at an upper portion thereof and extending in a second direction perpendicular to the channel pattern.

32. The semiconductor device of claim 31, wherein the first and the second conductive patterns are doped with impurities.

33. The semiconductor device of claim 31, wherein the channel pattern has a thickness of about 100 Å to about 300 Å.

34. The semiconductor device of claim 31, further comprising an insulation interlayer between the first and second conductive patterns, so that the insulation interlayer covers the channel pattern.

35. The semiconductor device of claim 31, wherein the gate electrode includes a first pillar having a first diameter and a second pillar that is formed on a top surface of the first pillar and has a second diameter greater than the first diameter, the first and second pillars being integrally formed with each other.

36. The semiconductor device of claim 35, wherein the channel pattern covers the first pillar.

37. The semiconductor device of claim 36, wherein the gate insulation layer is formed between the first pillar and the channel pattern and between the second pillar and the channel pattern.

38. The semiconductor device of claim 36, further comprising a capping layer enclosing the second pillar.

39. The semiconductor device of claim 38, wherein the gate insulation layer is formed between the gate electrode and the channel pattern and between the gate electrode and the capping layer.

40. The semiconductor device of claim 38, wherein the capping layer comprises silicon nitride.

41. A method of forming a gate structure, comprising:
forming a gate insulation layer on a substrate, the gate insulation layer including inner and outer surfaces; and
forming a gate electrode making contact with the inner surface of the gate insulation layer.

42. The method of claim 41, prior to forming a gate insulation layer, further comprising:
forming a sacrificial layer on the substrate;
forming a first opening on the sacrificial layer by partially etching the sacrificial layer, so that the substrate is partially exposed through the first opening; and
forming a single-crystalline silicon layer along an inner surface of the first opening, thereby forming a single-crystalline silicon pattern in accordance with a shape of the first opening, wherein an outer side surface of the gate insulation layer makes contact with upper and inner surfaces of the single-crystalline silicon pattern, and an inner side surface of the gate insulation layer encloses a space defined by the first opening.

43. The method of claim 42, further comprising forming a capping layer on the sacrificial layer, the capping layer having a second opening that partially exposes a surface of the sacrificial layer, wherein the sacrificial layer is etched away using the capping layer as an etching mask.

44. The method of claim 43, wherein the sacrificial layer is etched so that a bottom surface of the first opening is lower than a surface of the substrate.

45. The method of claim 44, wherein forming the gate electrode includes:
forming a conductive layer filling up the first and second openings; and
etching an upper portion of the conductive layer, so that the surface of the sacrificial layer is exposed.

46. The method of claim 42, wherein forming the sacrificial layer comprises forming a silicon germanium layer by an epitaxial process.

47. The method of claim 42, wherein the single-crystalline silicon layer is formed by an epitaxial process.

48. The method of claim 41, wherein the gate insulation layer includes at least one selected form the group consisting of a silicon oxide (SixOy, wherein x and y are positive numbers) layer, a silicon oxynitride (SiON) layer, a tantalum oxide (Ta₂O₅) layer, a tantalum oxynitride (TaON) layer, a titanium oxide (TiO₂) layer, an aluminum oxide (Al₂O₃) layer, a yttrium oxide (Y₂O₃) layer, a zirconium oxide (ZrO₂) layer, a hafnium oxide (HfO₂) layer, a barium titanate oxide (BaTiO₃) layer, a strontium titanate oxide (SrTiO₃) layer, and combinations thereof.

49. The method of claim 41, wherein the gate insulation layer is formed to a thickness of about 10 Å to about 70 Å.

50. The method of claim 41, wherein forming the gate electrode comprises forming a polysilicon layer doped with impurities.

51. The method of claim 50, further comprising forming a metal silicide layer on a top surface of the polysilicon layer.

52. The method of claim 51, wherein the metal silicide layer comprises at least one selected from the group consisting of tungsten silicide, titanium silicide, tantalum silicide, cobalt silicide, and nickel silicide.

53. The method of claim 41, wherein forming the gate electrode includes:
forming a polysilicon pattern into a cylindrical shape on an inner side surface of the gate insulation layer, the polysilicon pattern being doped with impurities; and
forming a metal silicide plug filling an inside of the cylindrical shaped polysilicon pattern.

54. The method of claim 41, wherein the gate electrode comprises at least one selected from the group consisting of tungsten, titanium, tantalum, cobalt, nickel, molybdenum, and ruthenium.

55. A method of manufacturing a semiconductor device, comprising:
forming a first conductive pattern on a substrate;
forming a second conductive pattern spaced apart from the first conductive pattern by a predetermined distance in a vertical direction;
forming a channel pattern including inner and outer side surfaces, the channel pattern making contact with the first and second patterns;
forming a gate insulation layer on the inner side surface of the channel pattern; and
forming a gate electrode making contact with the gate insulation layer.

56. The method of claim 55, wherein the first and second conductive patterns are partially overlapped with each other.

57. The method of claim 55, wherein the channel pattern has a pillar ring shape extending from the substrate in the vertical direction.

58. The method of claim 55, wherein the channel pattern is formed by the first and second conductive patterns.

59. The method of claim 55, wherein the first and second conductive patterns extend in horizontal direction different from each other.

60. The method of claim 55, wherein the first and second conductive patterns horizontally extend in a same direction, and the first conductive pattern extends longer than the second conductive pattern.

61. The method of claim 55, wherein forming the first conductive pattern includes:
forming a single-crystalline silicon layer on the substrate by an epitaxial process;
doping the single-crystalline silicon layer with first impurities, so that the single-crystalline silicon layer is transformed into a first conductive layer; and
patterning the first conductive layer.

62. The method of claim 61, further comprising forming a buffer oxide layer on the single-crystalline silicon layer.

63. The method of claim 62, wherein doping the single-crystalline silicon layer is carried out by an ion implantation process.

64. The method of claim 61, wherein the single-crystalline silicon is formed to a thickness of about 400 Å to about 600 Å.

65. The method of claim 61, before the first conductive pattern is formed, further comprising doping a surface portion of the substrate with second impurities having a conductive type different from that of the first impurities.

66. The method of claim 55, wherein forming the first conductive pattern includes:
forming a silicon germanium layer on the substrate by an epitaxial process;
forming a single-crystalline silicon layer on the silicon germanium layer by an epitaxial process;
doping the single-crystalline silicon layer with first impurities, so that the single-crystalline silicon layer is transformed into a first conductive layer; and
patterning the first conductive layer.

67. The method of claim 66, before the first conductive pattern is formed, further comprising doping a surface portion of the substrate with second impurities having a conductive type different from that of the first impurities.

68. The method of claim 55, further comprising forming a sacrificial layer on the substrate on which the first conductive pattern is formed.

69. The method of claim 68, wherein the sacrificial layer includes a silicon germanium layer formed by an epitaxial process.

70. The method of claim 68, further comprising planarizing the sacrificial layer.

71. The method of claim 68, wherein forming the sacrificial layer includes:
forming a first dummy layer on the substrate on which the first conductive pattern is formed;
planarizing the first dummy layer; and
forming a second dummy layer on the first dummy layer.

72. The method of claim 71, wherein the first dummy layer is planarized by a chemical mechanical polishing (CMP) process.

73. The method of claim 71, wherein the first dummy layer is planarized until the first conductive pattern is exposed.

74. The method of claim 71, wherein the second dummy layer is formed to a thickness of about 1000 Å.

75. The method of claim 68, wherein forming the second conductive pattern includes:
forming a single-crystalline silicon layer on the sacrificial layer by an epitaxial process;
doping the single-crystalline silicon layer with impurities, so that the single-crystalline silicon layer is transformed into a second conductive layer;
patterning the second conductive layer;

76. The method of claim 75, wherein the single-crystalline silicon layer is formed to a thickness of about 400 Å to about 600 Å.

77. The method of claim 75, further comprising forming a buffer oxide layer on the single-crystalline silicon layer.

78. The method of claim 68, further comprising forming a capping layer on the sacrificial layer and the second conductive layer.

79. The method of claim 78, wherein the capping layer comprises silicon nitride.

80. The method of claim 78, further comprising planarizing the capping layer.

81. The method of claim 78, further comprising forming an opening by partially and sequentially removing the capping layer, the second conductive pattern, the sacrificial layer, and the first conductive pattern, wherein the channel pattern is formed on an inner side surface of the opening.

82. The method of claim 81, wherein the channel pattern is formed on the inner side surface of the opening by a selective epitaxial process, the opening being defined by the second conductive pattern, the sacrificial layer and the first conductive pattern.

83. The method of claim 55, wherein the channel pattern comprises single-crystalline silicon.

84. The method of claim 55, wherein the channel pattern is doped with impurities by an in-situ process during the selective epitaxial process.

85. The method of claim 81, wherein forming the gate electrode includes:
forming a third conductive layer to a thickness so that the opening is covered with the third conductive layer; and
partially removing the third conductive layer until a top surface of the capping layer is exposed.

86. The method of claim 85, wherein the third conductive layer is removed using a chemical mechanical polishing (CMP) process.

87. The method of claim 85, further comprising: forming a hard mask on the capping layer correspondently to the second conductive pattern;
partially removing the capping layer using the hard mask to thereby form a capping pattern corresponding to the second conductive pattern;
removing the sacrificial layer from the substrate;
removing the hard mask; and
filling a space formed by removing the capping layer and the sacrificial layer with an insulation interlayer.

88. The method of claim 87, wherein the sacrificial layer is removed by a wet-etching process using an etchant in which an etching selectivity of the sacrificial layer with respect to the channel pattern is no less than about 50:1.

89. The method of claim 81, wherein the opening is formed so that a bottom surface of the opening is lower than a surface of the substrate.

90. The method of claim 55, wherein the channel pattern is formed to a thickness of about 100 Å to about 300 Å.

91. The method of claim 55, wherein the gate insulation layer includes at least one selected from the group consisting of a silicon oxide (SixOy, wherein x and y are positive numbers) layer, a silicon oxynitride (SiON) layer, a tantalum oxide (Ta₂O₅) layer, a tantalum oxynitride (TaON) layer, a titanium oxide (TiO₂) layer, an aluminum oxide (Al₂O₃) layer, a yttrium oxide (Y₂O₃3) layer, a zirconium oxide (ZrO₂) layer, a hafnium oxide (HfO₂)layer, a barium titanate oxide (BaTiO₃) layer, a strontium titanate oxide (SrTiO₃) layer, and combinations thereof.

92. The method of claim 55, wherein the gate electrode comprises polysilicon doped with impurities.

93. The method of claim 55, further comprising forming a metal silicide layer on a top surface of the gate electrode.

94. The method of claim 55, wherein forming the gate electrode includes:
forming a polysilicon pattern doped with impurities into a cylindrical shape on an inner side surface of the gate insulation layer; and
forming a metal silicide plug that fills up an inside of the cylindrical shaped polysilicon pattern.

95. The method of claim 55, wherein the gate electrode comprises at least one selected from the group consisting of tungsten, titanium, tantalum, cobalt, nickel, molybdenum, and ruthenium.

96. A method of manufacturing a semiconductor device, comprising:
forming a first conductive layer on a substrate;
patterning the first conductive layer to thereby form a first conductive pattern;
forming a sacrificial layer on the substrate and the first conductive pattern;
forming a second conductive layer on the sacrificial layer;
forming a channel pattern having a pillar ring shape, the channel pattern penetrating the second conductive layer and the sacrificial layer and making contact with the first conductive pattern;
forming a gate insulation layer on an inner side surface of the pillar ring shaped channel pattern;
forming a gate electrode making contact with the gate insulation layer; and
patterning the second conductive layer to form a second conductive pattern making contact with the channel pattern.

97. The method of claim 96, wherein the first and second conductive patterns cover lower and upper portions of the channel pattern, respectively.

98. The method of claim 96, further comprising a capping layer on the second conductive layer.

99. The method of claim 98, wherein forming the channel pattern includes:
forming an opening penetrating the second conductive layer, the sacrificial layer and the first conductive pattern from a top surface of the capping layer; and
forming a single-crystalline silicon layer on an inner side surface of the opening by an epitaxial process.

100. The method of claim 99, wherein forming the gate electrode includes:
forming a third conductive layer to a thickness so that the opening is covered with the third conductive layer ; and
partially removing the third conductive layer until a top surface of the capping layer is exposed.

101. The method of claim 98, wherein patterning the second conductive layer includes:
forming a hard mask on the capping layer correspondently to the second conductive pattern; and
partially removing the capping layer and the second conductive layer using the hard mask to thereby form a second conductive pattern.

102. The method of claim 101, further comprising:
removing the sacrificial layer using an etchant in which an etching selectivity of the sacrificial layer with respect to the channel pattern is no less than about 50:1;
filling a space with an insulation interlayer, the space being formed by removing the sacrificial layer and by partially removing the capping layer and the second conductive layer during the step of patterning the second conductive layer; and
removing the hard mask.

103. The method of claim 101, further comprising:
removing the sacrificial layer using an etchant in which an etching selectivity of the sacrificial layer with respect to the channel pattern is no less than about 50:1;
removing the hard mask and the capping layer remaining on the second conductive pattern; and
filling a space with an insulation interlayer, the space being formed by removing the sacrificial layer, by partially removing the second conductive layer during the step of patterning the second conductive layer, and by removing the capping layer remaining on the second conductive pattern.

104. The method of claim 96, wherein the first and second conductive layers are formed by an epitaxial process, the epitaxial process being performed using a processing gas including silicon source gas and a dopant source.
